(19) United States
(12) Patent Application Publication
(10) Pub. No.: US 2020/0098660 A1
(43) Pub. Date: Mar. 26, 2020

(54) SEMICONDUCTOR DEVICE

(71) Applicant: Mitsubishi Electric Corporation, Chiyoda-ku, Tokyo (JP)

(72) Inventors: Shuji WAKAIKI, Chiyoda-ku, Tokyo (JP); Shota SATO, Chiyoda-ku, Tokyo (JP); Kenta FUJII, Chiyoda-ku, Tokyo (JP); Takashi KUMAGAI, Chiyoda-ku, Tokyo (JP)

(73) Assignee: Mitsubishi Electric Corporation, Chiyoda-ku, Tokyo (JP)

(21) Appl. No.: 16/495,325

(22) PCT Filed: May 21, 2018
(86) PCT No.: PCT/JP2018/019455

§ 371 Date: Sep. 18, 2019

(30) Foreign Application Priority Data
May 26, 2017 (JP) 2017-104870

(51) Int. Cl. H01L 23/367; H01L 21/48

(52) U.S. Cl. CPC H01L 23/367; H01L 21/4882

(57) ABSTRACT

A semiconductor device includes a printed board, an electronic component, and a thermal diffuser. The electronic component and the thermal diffuser are bonded onto one main surface of the printed board. The electronic component and the thermal diffuser are electrically and thermally bonded to each other by a bonding material. The printed board includes an insulating layer and a plurality of radiation vias penetrating from the main surface to the other main surface of the printed board. At least a part of the plurality of radiation vias overlaps the electronic component, and at least another part of the plurality of radiation vias overlaps the thermal diffuser. At least a part of the plurality of radiation vias is disposed so as to overlap a heat radiator at a transmission viewpoint from the main surface of the printed board.

### TECHNICAL FIELD

The present invention relates to a semiconductor device, and particularly to a semiconductor device having excellent heat radiation to heat generated from an electronic component.

### BACKGROUND ART

There are electronic circuits, power supply devices, and driving electric circuits, such as a motor, in which semiconductors used for on-board (cars and industrial construction machines), vehicles (railroad vehicles), industrial instruments (processing machines, robots, and industrial inverters), and household electronic instruments are used, and hereinafter these are collectively referred to as semiconductor devices. In semiconductor devices, there is a strong demand for higher power, a low profile, and miniaturization. As a result, an amount of heat generated per unit volume of the electronic component mounted on the semiconductor device is largely increased, and there is a strong demand for a semiconductor device enabling the high heat radiation.

For example, Japanese Patent Laying-Open Nos. 6-77679 (PTD 1) and 11-345921 (PTD 2) disclose a semiconductor device that radiates the heat generated from the electronic component. In these PTDs, the electronic component is bonded to an upper portion of a printed board while a heat sink is bonded to a lower portion. A thermal conduction channel is formed in the printed board so as to penetrate the printed board from one of main surfaces to the other main surface. The heat generated from the electronic component can be transferred to the heat sink through the thermal conduction channel, and radiated from the heat sink to an outside.

### CITATION LIST

### Patent Document

PTD 1: Japanese Patent Laying-Open No. 6-77679

PTD 2: Japanese Patent Laying-Open No. 11-345921

### SUMMARY OF INVENTION

### Technical Problems

In the apparatus of Japanese Patent Laying-Open No. 6-77679, the thermal conduction channel is provided only in a portion of the printed board away from immediately below the electronic component. In the apparatus of Japanese Patent Laying-Open No. 11-345921, a thermal conduction hole is made only immediately below the electronic component. For this reason, because of a small area of a heat transferable region of the printed board and a small amount of heat conducted from the electronic component, the heat radiation is insufficient in the region from the electronic component to the heat sink below the electronic component. A fastening plate of the apparatus disclosed in Japanese Patent Laying-Open No. 6-77679 is fixed to the printed board only by a jig, and an air layer is generated between the printed board and the heat sink to lessen the heat radiation between the printed board and the heat sink.

An object of the present invention is to provide a semiconductor device, which can radially diffuse the heat around the electronic component and improve the heat radiation to the heat generated from the electronic component.

### Solution to Problem

According to one aspect of the present invention, a semiconductor device includes a printed board, an electronic component, and a thermal diffuser. The electronic component and the thermal diffuser are bonded onto one of main surfaces of the printed board. The electronic component and the thermal diffuser are electrically and thermally bonded to each other by a bonding material. The printed board includes an insulating layer and a plurality of radiation vias penetrating from one of the main surfaces to the other main surface. At least a part of the plurality of radiation vias overlaps the electronic component, and at least another part of the plurality of radiation vias overlaps the thermal diffuser. At least a part of the plurality of radiation vias is disposed so as to overlap a heat radiator at a transmission viewpoint from the other main surface of the printed board.

### Advantageous Effects of Invention

In the present invention, the heat can radially be diffused about the electronic component, and radiated immediately below the electronic component. Consequently, the present invention can provide the semiconductor device capable of further improving the heat radiation to the heat generated from the electronic component.

### BRIEF DESCRIPTION OF DRAWINGS

FIG. 1 is a schematic plan view illustrating a semiconductor device according to a first example of a first embodiment.

FIG. 2 is a schematic sectional view illustrating a semiconductor device of the first example of the first embodiment.

FIG. 3 is a schematic plan view illustrating a printed board before an electronic component and a thermal diffuser are mounted in the first example of the first embodiment.

FIG. 4 is a schematic plan view illustrating a semiconductor device according to a second example of the first embodiment.

FIG. 5 is a schematic sectional view illustrating a semiconductor device of the second example of the first embodiment.

FIG. 6 is a schematic sectional view illustrating a first step of a method for manufacturing the semiconductor device of the first example of the first embodiment.

FIG. 7 is a schematic sectional view illustrating a second step of the method for manufacturing the semiconductor device of the first example of the first embodiment.

FIG. 8 is a schematic sectional view illustrating a third step of the method for manufacturing the semiconductor device of the first example of the first embodiment.

FIG. 9 is a schematic plan view illustrating a heat transfer path from the electronic component in the first embodiment.

FIG. 10 is a schematic sectional view illustrating the heat transfer path from the electronic component in the first embodiment.

FIG. 11 is a graph in which thermal resistance values of the semiconductor device of the first embodiment and a semiconductor device of a comparative example are compared to each other.

FIG. 12 is a schematic plan view illustrating a size of each unit in a model of the semiconductor device of the first embodiment, the model being used to derive the graph in FIG. 11.

FIG. 13 is a schematic plan view illustrating the model of the semiconductor device of the first embodiment, the model being used to derive the graph in FIG. 11.

FIG. 14 is a graph illustrating a relationship between a distance from an edge of the electronic component to an outermost radiation via bonded to a thermal diffusion plate and a thermal resistance of the semiconductor device.

FIG. 15 is a schematic plan view illustrating a semiconductor device according to each example of second to fifth embodiments.

FIG. 16 is a schematic sectional view illustrating a semiconductor device according to a second embodiment.

FIG. 17 is a schematic sectional view illustrating a semiconductor device according to a third embodiment.

FIG. 18 is a schematic sectional view illustrating a first step of a method for manufacturing the semiconductor device of the third embodiment.

FIG. 19 is a schematic sectional view illustrating a second step of the method for manufacturing the semiconductor device of the third embodiment.

FIG. 20 is a schematic sectional view illustrating a third step of the method for manufacturing the semiconductor device of the third embodiment.

FIG. 21 is a schematic sectional view illustrating a fourth step of the method for manufacturing the semiconductor device of the third embodiment.

FIG. 22 is a schematic sectional view taken along the line A-A in FIG. 15 of a semiconductor device according to a fourth embodiment.

FIG. 23 is a schematic sectional view taken along the line B-B in FIG. 15 of the semiconductor device of the fourth embodiment.

FIG. 24 is a schematic sectional view illustrating a semiconductor device according to a first example of a fifth embodiment.

FIG. 25 is a schematic sectional view illustrating a semiconductor device according to a second example of the fifth embodiment.

FIG. 26 is a schematic enlarged sectional view illustrating a more preferable mode of a region XXVI surrounded by a dotted line in FIG. 24.

FIG. 27 is a schematic sectional view illustrating a semiconductor device according to each example of a sixth embodiment.

FIG. 28 is a schematic sectional view illustrating a semiconductor device according to a first example of the sixth embodiment.

FIG. 29 is a schematic sectional view illustrating a semiconductor device according to a second example of the sixth embodiment.

FIG. 30 is a schematic enlarged sectional view illustrating a part of a semiconductor device according to a seventh embodiment.

FIG. 31 is a schematic enlarged sectional view illustrating a mode of a region XXXI surrounded by a dotted line in FIG. 30.

FIG. 32 is a schematic enlarged plan view illustrating a part of a semiconductor device according to an eighth embodiment.

FIG. 33 is a schematic enlarged sectional view illustrating a part of the semiconductor device of the eighth embodiment.

FIG. 34 is a schematic plan view illustrating a semiconductor device according to a ninth embodiment.

FIG. 35 is a schematic sectional view illustrating a semiconductor device according to a first example of a tenth embodiment.

FIG. 36 is a schematic sectional view illustrating a semiconductor device according to a second example of the tenth embodiment.

FIG. 37 is a schematic sectional view illustrating a semiconductor device according to a comparative example for the semiconductor device of the first example of the tenth embodiment.

FIG. 38 is a schematic sectional view illustrating a semiconductor device according to a comparative example for the semiconductor device of the second example of the tenth embodiment.

FIG. 39 is a schematic sectional view illustrating a semiconductor device according to a first example of an eleventh embodiment.

FIG. 40 is a schematic sectional view illustrating a semiconductor device according to a second example of the eleventh embodiment.

FIG. 41 is a schematic sectional view illustrating a semiconductor device according to a third example of the eleventh embodiment.

FIG. 42 is a schematic sectional view illustrating a semiconductor device according to a fourth example of the eleventh embodiment.

FIG. 43 is a schematic plan view illustrating a semiconductor device according to each example of a twelfth embodiment.

FIG. 44 is a schematic sectional view illustrating a semiconductor device according to a first example of the twelfth embodiment.

FIG. 45 is a schematic sectional view illustrating a semiconductor device according to a second example of the twelfth embodiment.

### DESCRIPTION OF EMBODIMENTS

Hereinafter, exemplary embodiments will be described with reference to the drawings.

### First Embodiment

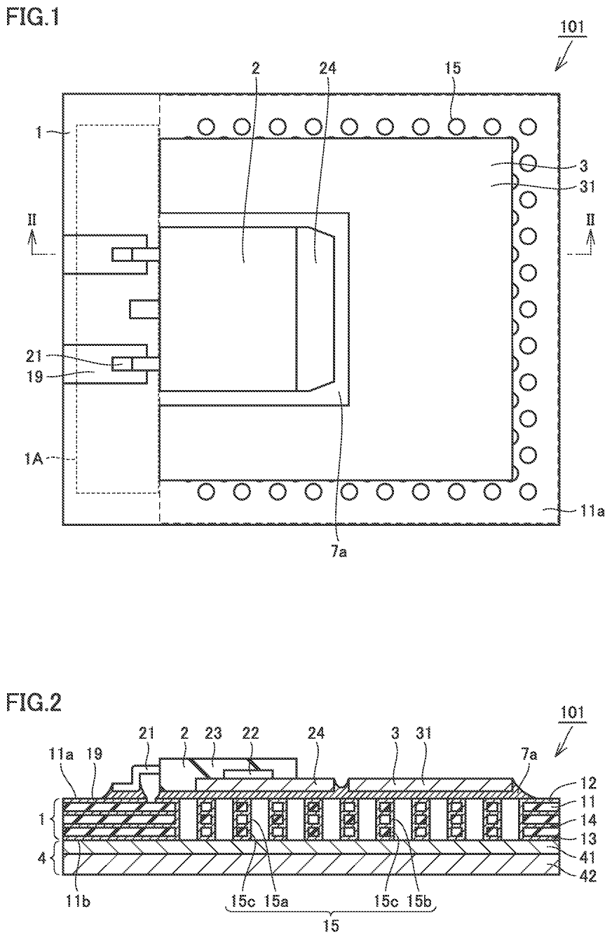

FIG. 1 illustrates a mode of a whole or a part of a semiconductor device according to a first example of a first embodiment at a transmission viewpoint from above, namely, in planar view from above. FIG. 2 is a schematic sectional view taken along the line II-II in FIG. 1, and illustrates a laminated structure of a printed board 1 and a heat radiator 4 in a region where an electronic component 2 and a thermal diffuser 3 (to be described later) are disposed. That is, when FIG. 1 illustrates a part of the semiconductor device, FIG. 1 illustrates a mode in which only a part of the whole semiconductor device is cut out. Referring to FIGS. 1 and 2, a semiconductor device 101 according to a first example of the first embodiment is a device used for a power conversion device mounted on a hybrid vehicle, an electric vehicle, an electric appliance, an industrial device, and the like. Semiconductor device 101 mainly includes printed board 1, electronic component 2, thermal diffuser 3, and heat radiator 4. As described below, semiconductor device 101 has a path through which heat generated by electronic component 2 is dissipated to an outside from heat radiator 4 below a radiation via 15 of printed board 1 through radiation via 15 immediately below electronic component 2 and a path through which the heat generated by electronic component 2 is dissipated from heat radiator 4 to the outside after the heat is diffused to thermal diffuser 3. The details will be described below. First, printed board 1 will be described.

Printed board 1 is a flat plate-shaped member constituting a base of entire semiconductor device 100. For example, printed board 1 has a rectangular shape in planar view. As illustrated in FIG. 2, printed board 1 includes an insulating layer 11, an upper conductor layer 12 and a lower conductor layer 13 as a plurality of conductor layers, and an internal conductor layer 14 as a plurality of other conductor layers.

Insulating layer 11 is a member constituting the base of entire printed board 1. In the first embodiment, insulating layer 11 has a rectangular flat plate shape, and is made of, for example, a glass fiber and an epoxy resin. However, the material of insulating layer 11 is not limited to the glass fiber and the epoxy resin. Alternatively, for example, insulating layer 11 may be made of an aramid resin and the epoxy resin.

Upper conductor layer 12 is formed on one of the main surfaces of insulating layer 11, namely, the upper main surface in FIG. 2. Lower conductor layer 13 is formed on the other main surface on an opposite side to one of the main surfaces of the insulating layer 11, namely, on the lower main surface in FIG. 2. However, not only the one of main surfaces 11a and the other main surface 11b of insulating layer 11 but also the upper surface of upper conductor layer 12 may be set to the uppermost surface of entire printed board 1, namely, main surface 11a, and the lower surface of conductor layer 13 may be set to the lowermost surface of entire printed board 1, namely, main surface 11b.

Further, internal conductor layer 14 is formed in insulating layer 11. Internal conductor layer 14 is disposed so as to be vertically separated from upper conductor layer 12 and lower conductor layer 13. Internal conductor layer 14 is opposed to upper conductor layer 12 and lower conductor layer 13 so as to be substantially parallel to upper conductor layer 12 and lower conductor layer 13. That is, internal conductor layer 14 is opposed to both the main surfaces of insulating layer 11 so as to be substantially parallel to both the main surfaces. Two internal conductor layers 14 are formed in FIG. 2. The number of internal conductor layers 14 is not limited to two, but may be other than two, or internal conductor layer 14 may not be formed. However, thermal conductivity of internal conductor layer 14 is higher than that of insulating layer 11, so that the case that internal conductor layer 14 is disposed can be higher than the case that internal conductor layer 14 is not disposed in the thermal conductivity of entire printed board 1.

Four conductor layers, namely, one upper conductor layer 12 on the one of the main surfaces, one lower conductor layer 13 on the other main surface, and two internal conductor layers 14 disposed between upper conductor layer 12 and lower conductor layer 13 are disposed as a plurality of conductor layers in printed board 1 as described above, but the number of conductor layers is not limited thereto. The same applies to the following embodiments. All of conductor layers 12, 13, 14 are spread (so as to be substantially parallel) along both the main surfaces of printed board 1. Conductor layers 12, 13, 14 are made of a material having good thermal conductivity such as copper, and each of conductor layers 12, 13, 14 has a thickness ranging from about 15 μm to about 500 μm. Conversely, printed board 1 includes a plurality of insulating layers 11 defined by conductor layers 12, 13, 14.

On the printed board 1, the plurality of radiation vias 15 are formed so as to penetrate from the one of the main surfaces to the other main surface of insulating layer 11. While spaced apart from each other with respect to a direction along main surface 11a of printed board 1, the plurality of radiation vias 15 are formed in a region overlapping electronic component 2 and a region overlapping the thermal diffuser 3 at the transmission viewpoint from main surface 11a of printed board 1. Printed board 1 is considered while divided into a first region and a second region. The first region is a region overlapping electronic component 2 at the transmission viewpoint from the side of the one of the main surfaces of printed board 1, and the second region is a region around the first region, namely, a region disposed outside the first region at the transmission viewpoint from the side of the one of the main surfaces of printed board 1. At this point, the plurality of radiation vias 15 are classified into a first radiation via 15a formed in the first region and a second radiation via 15b formed in the second region.

That is, radiation vias 15 is formed in both the first region and the second region. At least a part of the plurality of radiation vias 15 is first radiation via 15a overlapping electronic component 2 at the transmission viewpoint from main surface 11a of printed board 1. At least another part of the plurality of radiation vias 15 is second radiation via 15b overlapping thermal diffuser 3 at the transmission viewpoint from main surface 11a of printed board 1.

First radiation via 15a and second radiation via 15b are a hole made in a part of insulating layer 11, and a conductor film 15c made of copper or the like is formed on an inner wall surface of the hole. In this case, radiation via 15 (first radiation via 15a and second radiation via 15b) may be considered to include both the hole and conductor film 15c inside the hole depending on a situation, or considered to indicate only one of the hole and conductor film 15c. That is, in FIG. 2, first radiation via 15a and second radiation via 15b are a hole (hollow) except for conductor film 15c. However, first radiation via 15a and second radiation via 15b in FIG. 2 may be filled with a material having good thermal conductivity, for example, a conductive adhesive mixed with a silver filler or solder. In the latter, a member such as the conductive adhesive with which the hole is filled can be included in a constituent of radiation via 15. As described above, radiation via 15 formed by filling radiation via 15 with the conductive adhesive or the like can improve the heat radiation as compared with radiation via 15 in which the hole is hollow. This is because a conductive member such as the conductive adhesive has thermal conductivity higher than that of air. The semiconductor device in which the hole of radiation via 15 is filled with solder will be described in a third embodiment (to be described later).

The hole of radiation via 15 is formed into a columnar shape having a diameter of, for example, 0.6 mm in planar view, and the thickness of conductor film 15c on the inner wall surface is, for example, 0.05 mm. The hole is not limited to the columnar shape, but may be a quadrangular prism or a polygonal shape at the transmission viewpoint from above.

First radiation via 15a and second radiation via 15b intersect both main surfaces 11a, 11b of printed board 1 so as to be, for example, orthogonal to both the main surfaces 11a, 11b. Conductor layers 12, 13, 14 are disposed so as to spread into a flat shape from the first region to the second region of printed board 1, and provided so as to be along both the main surfaces of printed board 1, namely, be substantially parallel to both the main surfaces. For this reason, first radiation via 15a and second radiation via 15b are cross-connected to conductor layers 12, 13, 14. Conversely, the plurality of conductor layers 12, 13, 14 are cross-connected to each of the plurality of radiation vias 15. More specifically, conductor film 15c formed on the inner wall surface of the hole of radiation via 15 and conductor layers 12, 13, 14 are cross-connected to each other. As used herein, the cross connection means that the conductors are bonded together and electrically connected to each other.

Conductor layers 12, 13, 14 may be disposed so as to spread in a planar manner over the whole region overlapping printed board 1 (exactly the region except for the region overlapping the hole of radiation via 15 in printed board 1). Preferably conductor layers 12, 13, 14 are disposed at least in the region overlapping the region where radiation vias 15 are provided in the first and second regions (exactly the region sandwiched between a pair of radiation vias 15 adjacent to each other), and cross-connected to radiation vias 15. That is, the plurality of conductor layers 12, 13, 14 may be disposed not in the region overlapping the region where radiation vias 15 are not formed, such as a region 1A in FIG. 1, but only in the region overlapping the region where radiation vias 15 are provided (exactly the region sandwiched between the pair of radiation vias 15 adjacent to each other).

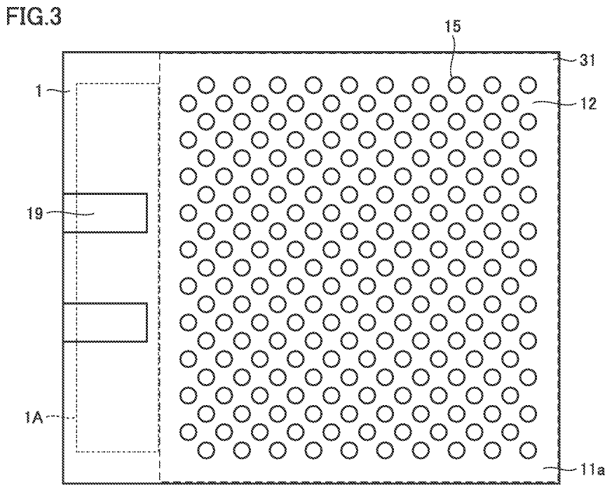

FIG. 3 illustrates a plan mode at the transmission viewpoint from the side of main surface 11a of printed board 1 before electronic component 2 and thermal diffuser 3 (to be described later) are mounted. Referring to FIG. 3, radiation vias 15 are not necessarily formed on the whole region on main surface 11a of printed board 1. That is, radiation via 15 is not formed in region 1A on the left side in FIG. 3, namely, the region to which a lead terminal 21 constituting electronic component 2 (to be described later) is connected. However, preferably conductor layers 12, 13, 14 are formed so as to extend in a planar manner in both region 1A and other regions where radiation vias 15 are formed. Consequently, an effect that the heat of electronic component 2 is diffused in the conductor layer is enhanced.

Region 1A on main surface 11a of printed board 1 is an area in which a wiring (not illustrated) is disposed because lead terminal 21 of electronic component 2 is connected to region A1. The wiring electrically connects electronic component 2 and another component. An electrode 19 formed in the same layer as upper conductor layer 12 is formed in main surface 11a in region 1A of printed board 1. Lead terminal 21 of electronic component 2 is bonded to electrodes 19 provided in a partial area of region 1A of printed board 1 by a bonding material 7a such as solder. As used herein, bonding means that a plurality of members are bonded together by solder or the like.

In FIGS. 1 to 3, the numbers of radiation vias 15 does not agree with one another. However, it is assumed that radiation vias 15 in FIGS. 1 to 3 correspond to one another. The same applies to the following drawings.

Referring to FIGS. 1 and 2 again, electronic component 2 and thermal diffuser 3 are bonded onto main surface 11a of printed board 1, namely, the upper surface of upper conductor layer 12. Electronic component 2 and thermal diffuser 3 (partly including a bonding material 7a) will be described below.

Electronic component 2 is a package in which a semiconductor chip 22 including at least any one selected from a group consisting of a MOSFET (Metal Oxide Semiconductor Field Effect Transistor), an IGBT (Insulated Gate Bipolar Transistor), a PNP transistor, an NPN transistor, a diode, and a control IC (Integrated Circuit) is sealed by a resin mold 23. For example, electronic component 2 has a rectangular planar shape. Because semiconductor chip 22 is included, a heating value of electronic component 2 is very large. For this reason, electronic component 2 has a heat radiation plate 24 as illustrated in FIG. 2. Heat radiation plate 24 is bonded to main surface 11a of printed board 1, namely, upper conductor layer 12 by bonding material 7a such as solder. Consequently, the heat generated from semiconductor chip 22 of electronic component 2 can efficiently be radiated through heat radiation plate 24. When heat radiation plate 24 is provided as in semiconductor device 101, electronic component 2 includes lead terminals 21, semiconductor chip 22, resin mold 23, and heat radiation plate 24.

Heat radiation plate 24 is intended to transfer the heat generated from semiconductor chip 22 to the outside. For this reason, for example, when the heat of semiconductor chip 22 can be transmitted from the side of lead terminal 21 to the outside, lead terminal 21 can be disposed as heat radiation plate 24, and lead terminal 21 can function as heat radiation plate 24. Any heat radiation plate can be used as long as the heat of semiconductor chip 22 can be transferred to the outside even if heat radiation plate 24 in FIG. 2 is electrically insulated from semiconductor chip 22 by sandwiching an insulating material between heat radiation plate 24 and semiconductor chip 22.

In FIG. 2, heat radiation plate 24 is disposed such that a part of the upper surface of heat radiation plate 24 and the side surface on the left side in FIG. 2 are covered with resin mold 23. Consequently, heat radiation plate 24 is fixed to resin mold 23. However, this is only an example, but the present invention is not limited to this mode.

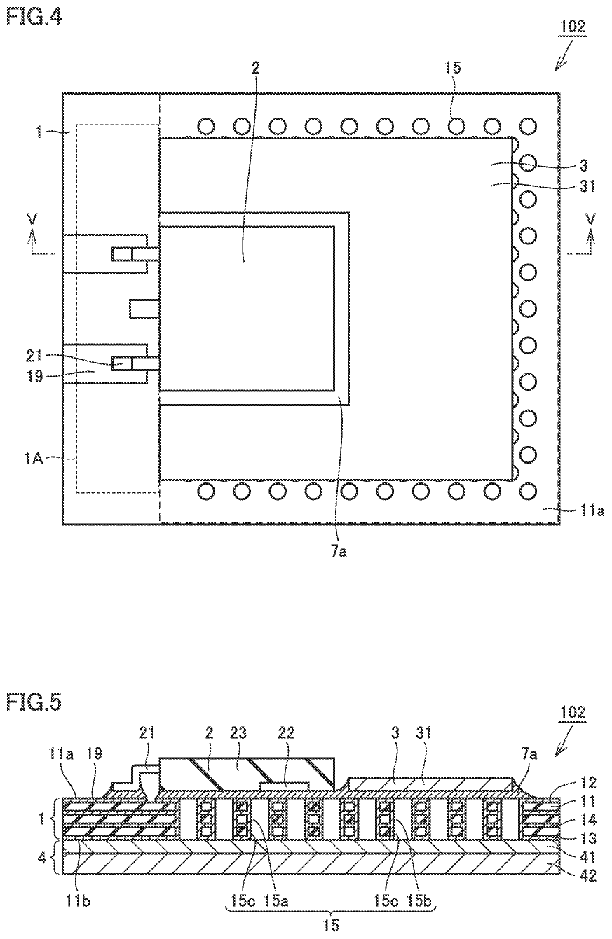

FIG. 4 illustrates a mode of a whole or a part of the semiconductor device according to a second example of the first embodiment at the transmission viewpoint from above, namely, in planar view from above. FIG. 5 is a schematic sectional view taken along a line V-V in FIG. 4, and illustrates the laminated structure of printed board 1 and heat radiator 4 in the region where electronic component 2 and thermal diffuser 3 are disposed. Referring to FIGS. 4 and 5, because a semiconductor device 102 of the second example of the first embodiment basically has the same configuration as semiconductor device 101, the same component is designated by the same reference numeral, and the overlapping description will be omitted. However, in semiconductor device 102, electronic component 2 does not include heat radiation plate 24, but electronic component 2 has what is called a full mold configuration in which the entire lower surface of resin mold 23 except for a portion of lead terminal 21 contacts with the bonding material 7a in the lower surface of heat radiation plate 24 with no use of heat radiation plate 24. Semiconductor device 102 is different from semiconductor device 101 in this point. That is, electronic component 2 of semiconductor device 102 includes lead terminal 21, semiconductor chip 22, and resin mold 23. Because resin mold 23 is hardly bonded by, for example, the solder that is the bonding material in the lower layer, resin mold 23 has a close contact configuration in which resin mold 23 is only in contact with the bonding material. When resin mold 23 of electronic component 2 is in contact with at least the bonding material, the heat radiation to the side of printed board 1 from the bonding material can be ensured to a certain extent. As used herein, the close contact means that a plurality of members are in contact with each other to exert attractive force weaker than the bonding.

Referring to FIGS. 1 and 2 again, thermal diffuser 3 has a role of radially spreading the heat from electronic component 2 to the outside at the transmission viewpoint from the upper side of electronic component 2. For this reason, thermal diffuser 3 has a shape surrounding the side of lead terminal 21 of rectangular electronic component 2, namely, three side surfaces except for the left side in FIG. 1. With this shape, thermal diffuser 3 can enhance efficiency of radially diffusion of the heat from electronic component 2. However, thermal diffuser 3 is not necessarily limited to such a shape.

Thermal diffuser 3 is constructed with a thermal diffusion plate 31. Preferably thermal diffusion plate 31 is made of, for example, copper. Consequently, the thermal conductivity, namely, the heat radiation of thermal diffusion plate 31 can be enhanced. Thermal diffusion plate 31 may be made of a ceramic material having a good thermal conductivity, such as aluminum oxide and aluminum nitride, in which a metal film such as copper is formed on the surface. Thermal diffusion plate 31 may be made of a metal material in which a nickel plating film and a gold plating film are formed on the surface of any alloy material selected from a group consisting of a copper alloy, an aluminum alloy, and a magnesium alloy. Thermal diffusion plate 31 is bonded to main surface 11a of printed board 1, namely, upper conductor layer 12 by bonding material 7a such as solder. Electronic component 2 is bonded onto upper conductor layer 12, to which thermal diffusion plate 31 is bonded, by bonding material 7a. The portion of upper conductor layer 12 to which thermal diffusion plate 31 is bonded and the portion of upper conductor layer 12 to which electronic component 2 is bonded are integral with each other. For this reason, electronic component 2 is bonded to upper conductor layer 12 that is the same as the portion of upper conductor layer 12 to which thermal diffusion plate 31 is bonded. However, electronic component 2 is bonded to a position different from a position where thermal diffusion plate 31 is bonded at the transmission viewpoint from above. Thermal diffusion plate 31 and electronic component 2 are electrically connected to each other.

As illustrated in FIG. 2, when the solder is used as bonding material 7a, bonding material 7a between electronic component 2 and thermal diffuser 3 forms a fillet at each of an end of electronic component 2 on the side of thermal diffuser 3 and an end of thermal diffuser 3 on the side of electronic component 2. As a result, the thickness of the bonding material 7a in the region between heat radiation plate 24 and thermal diffusion plate 31 can be increased as compared with the thickness of the bonding material 7a between electronic component 2 and upper conductor layer 12 and the thickness of the bonding material 7a between thermal diffuser 3 and upper conductor layer 12.

Electronic component 2, namely, heat radiation plate 24 and thermal diffuser 3, namely, thermal diffusion plate 31 are electrically and thermally connected to each other by bonding material 7a such as solder. The electrical connection between electronic component 2 and thermal diffuser 3 means that electronic component 2 and thermal diffuser 3 are connected to each other by not an insulating material but a member called an electrically conductive material, such as solder, which has a low electric resistance value. The thermal connection between electronic component 2 and thermal diffuser 3 means that electronic component 2 and thermal diffuser 3 are connected to each other by not a heat insulating material but a material, such as solder, which is said to have a low thermal resistance.

More specifically, heat radiation plate 24 of electronic component 2 and thermal diffusion plate 31 of thermal diffuser 3 are bonded together in a left-right direction in FIG. 2 with bonding material 7a interposed therebetween. When thermal diffusion plate 31 is made of a conductive material such as a metal material, the current is passed through thermal diffusion plate 31 bonded to electronic component 2 by bonding material 7a such as solder, so that a resistance value of upper conductor layer 12 on printed board 1 can be decreased. Consequently, thermal diffusion plate 31 can not only diffuse the heat from electronic component 2, but also reduce a conduction loss of upper conductor layer 12 and the like formed on printed board 1. Both electronic components 2 and thermal diffuser 3 are bonded onto the same surface, namely, main surface 11a of printed board 1, so that electronic components 2 and thermal diffuser 3 can automatically be bonded regardless of the order of joining electronic components 2 and thermal diffuser 3 using, for example, the same automatic component mounter (mounter). For this reason, a process of mounting electronic components 2 and thermal diffuser 3 on printed boards 1 can be simplified, and performed at low cost with high efficiency.

For example, in the case that the package of electronic component 2 is a semiconductor package model number TO-252, a size of the package varies by about ±0.2 mm. The variation is not limited to the model number TO-252, but the size of the package of electronic component 2 varies typically from about ±0.01 mm to ±1 mm. For this reason, it is preferably assumed that an interval between electronic component 2 and thermal diffuser 3 is greater than or equal to 0.05 mm and less than or equal to 5 mm, including an error of a drive dimension of the automatic component mounter. When the distance between electronic component 2 and thermal diffuser 3 exceeds 5 mm, the thermal resistance between electronic component 2 and thermal diffuser 3 increases, and the effect of thermal diffusion of thermal diffuser 3 decreases. For this reason, preferably the interval between electronic component 2 and thermal diffuser 3 is less than or equal to 5 mm. When the drive dimension of the automatic component mounter has the large error, there is a risk that the interval between electronic component 2 and thermal diffuser 3 exceeds 5 mm. From the viewpoint of preventing such a defect, preferably electronic component 2 and thermal diffuser 3 are temporarily fixed before mounted on printed board 1, and electronic component 2 and thermal diffuser 3 are simultaneously mounted using the automatic component mounter. Consequently, the interval between electronic component 2 and thermal diffuser 3 can be set less than or equal to 5 mm, and a yield of the mounting process can be improved.

As described above, thermal diffuser 3 is bonded to electronic component 2 by bonding material 7a such as solder, and bonded to main surfaces 11a of printed board 1. Consequently, the heat generated from electronic component 2 can be diffused in the direction of main surfaces 11a so as to be radially transferred to thermal diffuser 3 through bonding material 7a. Electronic component 2 is bonded to main surfaces 11a by bonding material 7a. For this reason, not only the heat can directly be transferred from electronic component 2 to heat radiator 4 immediately below electronic component 2, but also the heat can be transferred from thermal diffuser 3 to heat radiator 4 immediately below thermal diffuser 3 after diffused from electronic component 2 to thermal diffuser 3.

Thermal diffusion plate 31 is bonded to main surface 11a of printed board 1 by bonding material 7a so as to close the holes of the plurality of second radiation vias 15b in the second region except for the region overlapping electronic component 2 in the plurality of radiation vias 15 of printed board 1 from above. On the other hand, heat radiation plate 24 of electronic component 2 is bonded to main surface 11a of printed board 1 by the bonding material 7a so as to close the holes of the plurality of first radiation vias 15a in the first region of the region overlapping the electronic component 2 in the plurality of radiation vias 15 of printed board 1 from above. Because radiation via 15 is not formed in region 1A in FIGS. 1 and 2, thermal diffusion plate 31 is not disposed. However, the present invention is not limited thereto.

When the solder is used as bonding material 7a bonding the above members, an intermetallic compound is formed at a bonding interface between bonding material 7a and electronic component 2 bonded to bonding material 7a and a bonding interface between upper conductor layer 12 and thermal diffusion plate 31, which allows the decrease in a contact thermal resistance at the bonding interface. Preferably the solder is used as bonding material 7a, but another material, such as a conductive adhesive and nano silver, which has the good thermal conductivity other than the solder, may be used.

Preferably thermal diffuser 3 has flexural rigidity higher than that of printed board 1, namely, a large product of Young's modulus and sectional secondary moment. Consequently, the rigidity of the structure constructed with printed board 1 and thermal diffusion plate 31 in semiconductor device 101 can be enhanced, and printed board 1 can hardly deformed against external force such as fixation and vibration.

When the thickness of thermal diffusion plate 31 is decreased, the heat conductivity is decreased, and the heat radiation to electronic component 2 becomes insufficient. On the other hand, when thermal diffusion plate 31 is too thick, thermal diffusion plate 31 cannot be mounted using the same mounter as the mounter that mounts electronic component 2. This is because the thickness of thermal diffusion plate 31 exceeds an upper limit of the thickness of the component that is mountable using the mounter. In this case, because thermal diffusion plate 31 cannot be mounted using an automatic machine, mounting cost is increased. In consideration of the above, preferably the thickness of thermal diffusion plate 31 is greater than or equal to 0.1 mm and less than or equal to 100 mm, and is set to, for example, 0.5 mm.

The thick thermal diffusion plate 31 may be formed into a block shape instead of the plate shape. Thermal diffuser 3 may have a configuration in which a plurality of thermal diffusion plates 31 are stacked. When thermal diffuser 3 is formed by stacking plates used widely, the manufacturing cost can be reduced, and the heat radiation of thermal diffuser 3 can be improved.

Heat radiator 4 will be described below. For example, heat radiator 4 is laminated on the entire surface of printed board 1 on the side of main surface 11b. Heat radiator 4 includes a heat radiation member 41 and a cooling body 42. For example, printed board 1 and heat radiator 4 may be bonded to each other by bonding material 7a, or be in close contact with each other so as to touch simply with each other. In semiconductor device 101 of FIG. 2, as an example, electronic component 2, printed board 1, heat radiation member 41, and cooling body 42 are laminated in this order from the upper side to the lower side in FIG. 2. However, contrarily, in the heat radiator 4, cooling body 42 and heat radiation member 41 may sequentially be laminated from the upper side to the lower side in FIG. 2. That is, the laminating order of heat radiation member 41 and cooling body 42 in heat radiator 4 does not matter.

When heat radiator 4 is laminated on the entire surface of the printed board 1 on the side of main surface 11b, heat radiator 4 is disposed so as to overlap all first heat radiating vias 15a and second heat radiating vias 15b of printed board 1 in planar view. However, in the first embodiment, at least a part of the plurality of radiation vias 15 is disposed so as to overlap heat radiator 4 at the transmission viewpoint from main surface 11b of printed board 1. In this sense, heat radiator 4 may have a mode overlapping only with at least a part of main surface 11b of printed board 1. For example, heat radiation member 41 and cooling body 42 may be disposed so as to contact closely with main surface 11b only in the region overlapping electronic component 2 in planar view and the region adjacent thereto.

Preferably heat radiation member 41 is made of a material having an electrical insulating property and the good thermal conductivity. Specifically, preferably heat radiation member 41 is formed by a sheet in which particles of aluminum oxide, aluminum nitride, or the like are mixed in a silicone resin. This is because aluminum oxide or aluminum nitride has the good thermal conductivity and the electrical insulating property. However, heat radiation member 41 may be grease or an adhesive instead of the sheet. Heat radiation member 41 may be a non-silicone resin as long as the heat conductivity is high.

Heat radiation member 41 may be constructed with a conductor layer having the good thermal conductivity and an electrical insulating layer. Heat radiation member 41 diffuses the heat from electronic component 2 to the outside of electronic component 2 by thermal diffusion plate 31, and the diffused heat is transferred to lower conductor layer 13 of printed board 1 by radiation via 15. When heat radiation member 41 has the conductor layer capable of diffusing the heat, the heat can further radially be diffused outward in planar view by the conductor layer.

Cooling body 42 is a rectangular flat-plate shaped member made of a metallic material having the good thermal conductivity. For example, cooling body 42 may be a casing, a heat pipe, or a heat radiation fin. Specifically, preferably cooling body 42 is made of, for example, aluminum. However, cooling body 42 may also be made of copper, an aluminum alloy, or a magnesium alloy. Cooling body 42 is disposed immediately below or immediately above heat radiation member 41. For this reason, in FIG. 2, cooling body 42 is thermally connected to printed board 1 through heat radiation member 41. In other words, heat radiation member 41 touches with, is in close contact with, or is bonded to the upper or lower main surface of cooling body 42. Although not illustrated, preferably a water-cooled type or air-cooled type cooling mechanism is provided on the lower side of cooling body 42 so as to touch with cooling body 42.

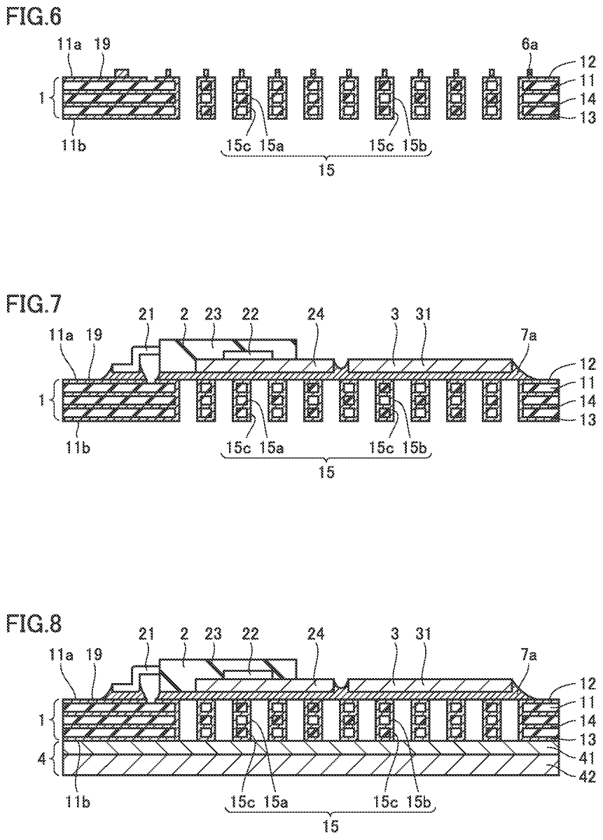

FIGS. 6 to 8 are schematic sectional views illustrating a mode in each process of manufacturing semiconductor device 101 of the first example of the first embodiment. With reference to FIGS. 6 to 8, an outline of a method for manufacturing semiconductor device 101, in particular, focusing on the process of mounting electronic component 2 and thermal diffuser 3 will be described below.

Referring to FIG. 6, printed board 1 having the mode in FIG. 2 is prepared, and solder paste 6a is supplied onto main surfaces 11a, namely, upper conductor layer 12. Preferably a plurality of solder pastes 6a are supplied to each region sandwiched between a pair of adjacent radiation vias 15 formed in printed board 1 in the form of dots in planar view. Preferably solder paste 6a is printed by a known printing method in a region separated by greater than or equal to 100 μm in the direction along main surface 11a of printed board 1 from an outer edge of the hole of the plurality of radiation vias 15.

Solder paste 6a is supplied onto printed board 1 as illustrated in FIG. 6 by performing a known solder printing process using a metal mask.

Referring to FIG. 7, electronic component 2 and thermal diffuser 3, namely, thermal diffusion plate 31 is mounted on solder paste 6a, and a known heating reflow process is performed in this state. The process of mounting electronic component 2 and thermal diffuser 3 is performed as an automatic process by the mounter. Solder paste 6a melts and flows along the surface of upper conductor layer 12, namely, main surface 11a by the reflow process, and is formed as a layered bonding material 7a. At this point, bonding material 7a that melts and flows does not flow into first radiation via 15a and second radiation via 15b. This is because solder paste 6a is printed in the region away from first radiation via 15a and second radiation via 15b in the process of FIG. 6. Although bonding material 7a flows immediately below resin mold 23 of electronic component 2, bonding material 7a is not bonded to the resin material, but simply touch with and contact closely with resin mold 23. Bonding material 7a bonds heat radiation plate 24 and thermal diffusion plate 31 of electronic component 2 to upper conductor layer 12. Bonding material 7a bonds lead terminals 21 of electronic component 2 to electrode 19 of printed board 1. An appearance inspection step of inspecting the mounting state is performed after the bonding with bonding material 7a.

Referring to FIG. 8, heat radiation member 41 and cooling body 42 are disposed in this order from the upper side to the lower side so as to be in close contact with each other and so as to be in contact with lower conductor layer 13 of printed board 1, whereby heat radiator 4 is provided. Conversely, cooling body 42 and heat radiation member 41 may be laminated such that cooling body 42 is disposed on the upper side and such that heat radiation member 41 is disposed on the lower side, and heat radiator 4 may be provided. Alternatively, cooling body 42 and heat radiation member 41 may be bonded together by bonding material 7a or the like. Thus, semiconductor device 101 in FIG. 2 is formed.

With reference to FIGS. 9 to 14, the advantageous effect of the first embodiment will be described below. Sometimes the contents of effect description of each member partially overlaps each other.

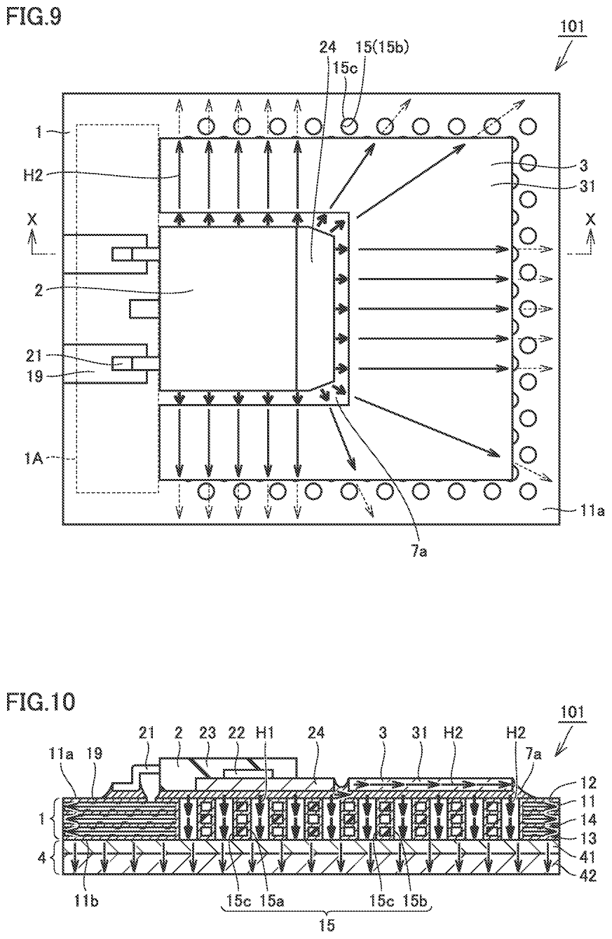

FIG. 9 illustrates a heat conduction path of whole semiconductor device 101 at the transmission viewpoint from above. FIG. 10 illustrates a heat conduction path in a sectional view taken along line X-X in FIG. 9 of semiconductor device 101. Referring to FIGS. 9 and 10, part of the heat generated from electronic component 2 by the drive of semiconductor device 101 is conducted downward (toward the side of diffusion radiator 4) through first radiation via 15a formed in printed board 1 below electronic component 2 as indicated by an arrow of heat H1 in FIG. 10. Although not illustrated, heat H1 also passes through upper conductor layer 12, lower conductor layer 13, or internal conductor layer 14, so that heat H1 is radially diffused toward the second region around (outside) electronic component 2 in FIG. 10.

Another part of the heat generated from electronic component 2 is conducted to thermal diffusion plate 31, which is bonded to electronic component 2 with bonding material 7a interposed therebetween in the direction along the main surface indicated by an arrow of heat H2 in FIGS. 9 and 10, and radially diffused in the direction along the main surface in thermal diffusion plate 31. This is because bonding material 7a bonding electronic component 2 and thermal diffusion plate 31 is a conductive material such as a solder and is excellent in thermal conductivity. The heat transferred to thermal diffusion plate 31 is conducted downward (on the side of heat radiator 4) through second radiation via 15b formed in printed board 1 below thermal diffusion plate 31. Part of heat H2 that passes through second radiation via 15b passes through upper conductor layer 12, lower conductor layer 13, or internal conductor layer 14, whereby the part of heat H is radially diffused toward second region around (outside) electronic component 2 in FIG. 10.

As described above, in the first embodiment, the heat of the electronic component 2 to be transferred through two routes, namely, a route (the path of heat H1 indicated by the arrow) in which the heat is transferred downward (the side of heat radiation portion 4) through first radiation via 15a and a route (the path of heat H2 indicated by the arrow) in which the heat is conducted to the outside (second region side) through second radiation via 15b. The reason why the heat can be conducted through the two routes in this way is attributed to the following fact. That is, thermal diffusion plate 31 is bonded onto main surfaces 11a similarly to electronic component 2, so that heat H2 generated from electronic component 2 can highly efficiently be transferred to thermal diffusion plate 31 through bonding material 7a, and highly efficiently be conducted from thermal diffusion plate 31 to heat radiator 4. This is also because radiation vias 15a, 15b extending in the direction intersecting the main surface of printed board 1 and conductor layers 12, 13, 14 extending along the main surface are cross-connected to each other. This effect is further enhanced by existence of thermal diffusion plate 31 and heat radiator 4 disposed on main surface 11b of printed board 1.

Heat H1 and heat H2 moved downward in printed board 1 reach lower conductor layer 13 in the region immediately below electronic component 2 and thermal diffusion plate 31 and the region outside electronic component 2 and thermal diffusion plate 31. Then, heat H1 and heat H2 are conducted to cooling body 42 through lower heat radiation member 41. Although not illustrated, heat H1 and heat H2 conducted to cooling body 42 are radiated to a water-cooled type or air-cooled type cooling mechanism provided on the lower side in FIG. 10.

As described above, in semiconductor device 101 of the first embodiment, thermal diffusion plate 31 is bonded onto main surfaces 11a similarly to electronic component 2, and the heat of the electronic component 2 can be radiated downward through the route passing through first radiation via 15a and the routes passing through second radiation via 15b. For this reason, the efficiency of the downward heat radiation can be largely enhanced as compared with the case that the heat can be radiated only from first radiation via 15a immediately below electronic component 2 or the case that the heat can be radiated only from second radiation via 15b far from electronic component 2.

In particular, the effect that enhances the heat radiation efficiency from second radiation via 15b in semiconductor device 101 of the first embodiment is very large because thermal diffusion plate 31 is disposed. As compared with the case that thermal diffusion plate 31 is not disposed, the heat can efficiently be radiated to cooling body 42 through heat radiation member 41 by disposing thermal diffusion plate 31.

In semiconductor device 101 of the first embodiment, for example, as illustrated in FIGS. 1 and 9, radiation vias 15 may be formed not only in the region immediately below thermal diffusion plate 31 but also outside thermal diffusion plate 31. Consequently, not only the heat generated from electronic component 2 is transferred downward through radiation vias 15 in the regions immediately below electronic component 2 and thermal diffusion plate 31, but also the heat diffused outward from thermal diffusion plate 31 can be transferred downward through radiation via 15 immediately below thermal diffusion plate 31.

As described above, conductor layers 12, 13, 14 can radially diffuse heat H1 and heat H2 of electronic component 2 toward an outer peripheral side similarly to thermal diffusion plate 31.

As described above, because the heat is radiated to the outside, an area of the heat-radiating region is enlarged, and the effect that enhances the heat radiation is further increased. Consequently, the heat radiation can further be improved when a contact area between cooling body 42 and printed board 1 can sufficiently be increased.

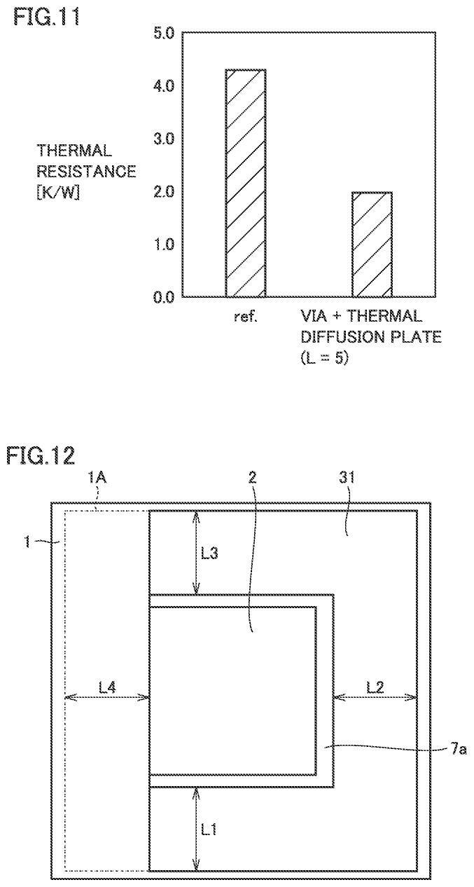

With reference to FIG. 11, how much the efficiency of the heat radiation is improved by the existence of both radiation via 15 thermal diffusion plate 31 as compared to the case that only radiation via 15 is provided will be described. Specifically, a result that a radiation resistance in the heat conduction is considered using the thermal resistance value with respect to the configuration as semiconductor device 101 including radiation via 15 and thermal diffusion plate 31 and the configuration as a comparative example not including second radiation via 15b and thermal diffusion plate 31 (but including only first radiation via 15a) is illustrated.

As used herein, the term of “thermal resistance” is an index representing difficulty of the conduction of a temperature, and means a temperature rise value per unit heating value. In semiconductor device 101 of the first embodiment, a thermal resistance (Rₜₕ) in the region in a vertical direction from electronic component 2 to cooling body 33 is given by the following equation (1). In the equation (1), Sᵢ (m²) is a heat transfer area of each member, lᵢ (m) is a thickness of each member, λᵢ (W/(m·K)) is thermal conductivity of each member, Q (W) is an amount of passing heating value, and Thᵢ (K) and Tₗ(K) are temperatures on high and low temperature sides.

$$\begin{matrix}[ Mathematical Formula 1 ] & \\ {R}_{th} = \sum \frac{{l}_{i}}{{λ}_{i} {S}_{i}} = \sum \frac{{Th}_{i} - {Tl}_{i}}{Q} & ( 1 )\end{matrix}$$

A model used to calculate a thermal resistance will be described below. Printed board 1 has the size of 25×25 mm at the transmission viewpoint from above, and the thickness of 1.65 mm. Electronic component 2 has the size of 10×10 mm at the transmission viewpoint from above, and electronic component 2 is bonded to a central portion of printed board 1 (although different from FIGS. 1 and 4). That is, the interval between edges when electronic component 2 is viewed from above is substantially equal to the interval between edges when printed board 1 substantially parallelly opposed to the edges of electronic component 2 is viewed from above. Each of upper conductor layer 12, lower conductor layer 13, and internal conductor layer 14 has a four-layer structure having the thickness of 105 μm (see FIG. 2). In printed board 1, 25 first radiation vias 15a are disposed immediately below electronic component 2 at equal intervals, and 63 second radiation vias 15b are disposed around first radiation vias 15a at equal intervals. Radiation via 15 has a cylindrical shape, the hole of radiation via 15a has a diameter of 0.6 mm when viewed from above, and the conductor film on the inner wall surface of the hole has the thickness of 0.05 mm.

Thermal diffusion plate 31 of thermal diffuser 3 in the above model has an outer size of 5×15 mm and the thickness of 1 mm at the transmission viewpoint from above, is disposed so as to surround electronic component 2, and covers second radiation via 15b from above. Electronic components 2 and thermal diffusion plate 31 that are aligned in the direction along the main surface are bonded to each other by bonding material 7a of solder. Heat radiation member 41 has the size of 5×15 mm at the transmission viewpoint from above and the thickness of 0.4 mm.

In the above model, upper conductor layer 12, lower conductor layer 13, internal conductor layer 14, conductor film 15c, and thermal diffusion plate 31 are made of copper, and have the thermal conductivity of 398 W/(m·K). Heat radiation member 41 has the thermal conductivity of 2.0 W/(m·K).

The model of semiconductor device 101 of the first embodiment and the model of the comparative example are different from each other only in the number of radiation vias 15 (the comparative example includes only the first radiation vias 15a, the first embodiment includes first radiation vias 15a and second radiation vias 15b) and the existence of thermal diffusion plate 31, and the model of semiconductor device 101 of the first embodiment and the model of the comparative example are identical to each other in other configurations including the sizes are the same.

Using the above models, the thermal resistance value was simulated for semiconductor device 101 and the comparative example by thermal analysis software based on the equation (1). FIG. 11 illustrates the result. “ref” in FIG. 11 represents the model of the comparative example, “via+thermal diffusion plate” represents the model of the semiconductor device 101 of the first embodiment, and the vertical axis represents the simulation result of the thermal resistance. With reference to FIG. 11, second radiation via 15b and thermal diffusion plate 31 are provided like semiconductor device 101 of the first embodiment, which allows the thermal resistance to be reduced by about 53% as compared with the comparative example in which second radiation via 15b and thermal diffusion plate 31 are not provided. Because the small thermal resistance means the high heat radiation, it can be seen from this result that the heat radiation is improved as compared with the comparative example when second radiation via 15b and thermal diffusion plate 31 are provided like semiconductor device 101 of the first embodiment.

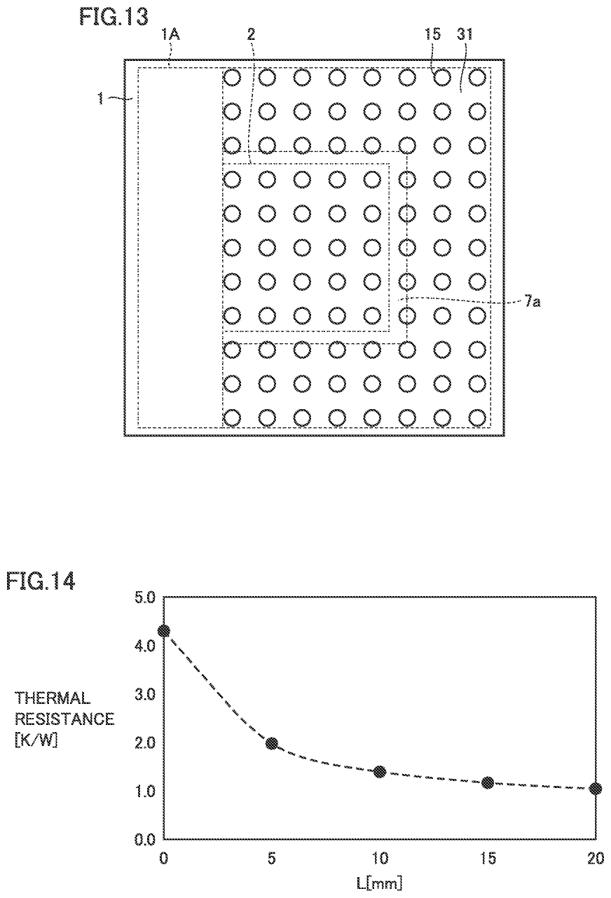

With reference to FIGS. 12 to 14, a studying result of the region where radiation via 15 bonded to thermal diffusion plate 31 should be disposed will be described below. Referring to FIGS. 12 and 13, FIGS. 12 and 13 basically illustrate the same model as semiconductor device 101 of the first embodiment used for the calculation of the thermal resistance, and the interval between the edge in each direction when electronic component 2 is viewed from above and the outermost edge in each direction of thermal diffusion plate 31 adjacent to the outside when electronic component 2 is viewed from above is indicated by L1, L2, L3. As described above, in the model, because the distances between the edges in each direction when electronic component 2 is viewed from above and the adjacent edges in each direction of thermal diffusion plate 31 are substantially equal to each other, distances L1 to L3 are substantially equal to one another. In semiconductor device 101, basically second radiation via 15b is not formed in region 1A (see FIG. 1), and second radiation via 15b does not exist on the side of a dimension L4 in FIGS. 12 and 13. However, dimension L4 is indicated as a reference in the same way as other directions.

A horizontal axis of the graph in FIG. 14 indicates a distance from each edge (corresponding to a rectangular side) in planar view of electronic component 2 to the outermost portion of thermal diffusion plate 31 on the side of three directions L1 to L3 in which thermal diffusion plate 31 is disposed, and a vertical axis of the graph indicates the thermal resistance value of semiconductor device 101 of each model. Referring to FIG. 14, with increasing sizes L1 to L3 (that is, with enlarging region where thermal diffusion plate 31 and second radiation vias 15b are formed), the thermal resistance is decreased to improve the heat radiation efficiency. However, as can be seen from FIG. 14, the decrease of the thermal resistance value is saturated when the values of L1 to L3 become 20 mm, and the change amount of the thermal resistance is smaller than that in the region where L1 to L3 are less than or equal to 20 mm even if the values of L1 to L3 are further increased to bond thermal diffusion plate 31 and radiation via 15 by bonding material 7a in the region where L1 to L3 are greater than or equal to 20 mm.

It can be said that preferably thermal diffusion plate 31 is disposed so as to be bonded to second radiation via 15b within the sizes L1 to L3, namely, the distance range of less than or equal to 20 mm from the edge of electronic component 2.

In the first embodiment, not only first radiation via 15a is formed in the first region of printed board 1, but also second radiation via 15b is formed in the second region around the first region. Consequently, the mechanical rigidity of printed board 1 is decreased as compared with the case that second radiation via 15b is not formed. However, bending rigidity of the structure constructed with printed board 1 and thermal diffusion plate 31 becomes higher than that of single printed board 1 by bonding thermal diffusion plate 31 to upper conductor layer 12 on main surface 11a of printed board 1 using bonding material 7a. This enables the prevention of the deformation of printed board 1.

### Second Embodiment

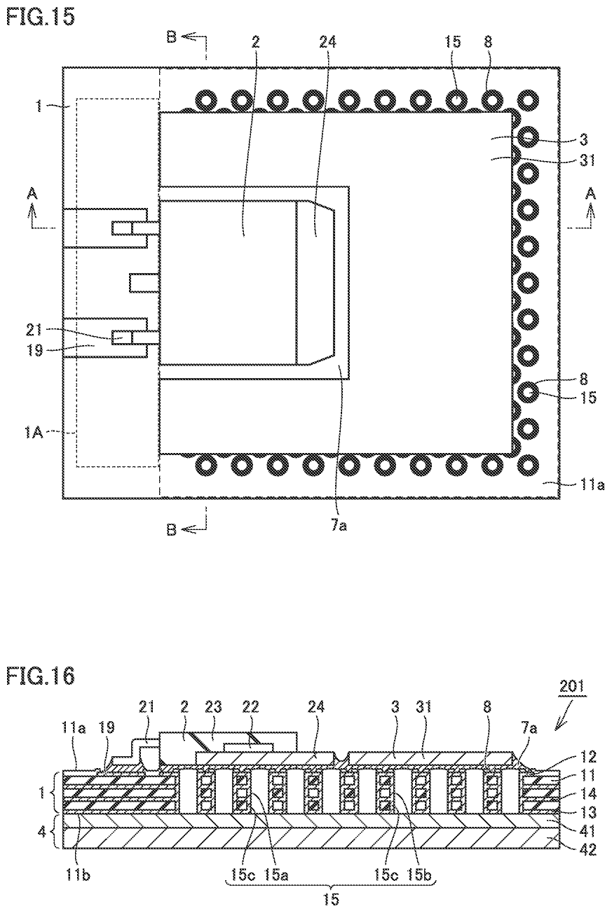

FIG. 15 collectively illustrates a mode of a whole or a part of the semiconductor device of each of second to fifth embodiments at a transmissive viewpoint from above, namely, in planar view from above. FIG. 16 is a schematic sectional view taken along a line A-A in FIG. 15 in the second embodiment, and illustrates a lamination structure of printed board 1 and heat radiator 4 in the region where electronic component 2 and thermal diffuser 3 are disposed. Referring to FIGS. 15 and 16, because a semiconductor device 201 of the second embodiment has basically the same configuration as that of semiconductor device 101, the same component is designated by the same reference numeral, and the overlapping description will be omitted. However, in semiconductor device 201, for example, a circular protrusion 8 is formed so as to surround first radiation via 15a and second radiation via 15b in the region adjacent to first radiation via 15a and second radiation via 15b in planar view on upper and lower conductor layer 12. Semiconductor device 201 is different from the semiconductor device 101 that does not include the protrusion 8 in this point.

For example, protrusion 8 is made of a solder resist, and has a shape extending upward in FIG. 16 from upper conductor layer 12. As described above, in the second embodiment, protrusion 8 is disposed on main surface 11a of printed board 1. Electronic component 2 and thermal diffuser 3 are disposed so as to overlap protrusion 8 at the transmission viewpoint from main surface 11a of printed board 1. Protrusion 8 is formed in the periphery of radiation via 15 in planar view so as to have a circular shape or an elliptical shape in the sectional view of FIG. 16. However, the present invention is not limited to the circular shape or the elliptical shape. For example, protrusion 8 may be formed to have a rectangular shape in the sectional view of FIG. 16.

A method for manufacturing semiconductor device 201 of the second embodiment, in particular, a method for manufacturing protrusion 8 will briefly be described. For example, protrusion 8 may be a solder resist formed by known resist printing in a process of manufacturing a printed board, or may be a pattern formed by known silk printing or symbol printing. When the solder resist or the pattern is used, since protrusion 8 can be formed by a general printed board manufacturing process, protrusion 8 can inexpensively be manufactured with no use of a special process. In addition to the solder resist, the silk, and the symbol mark, a resin sheet or an appropriate combination thereof may be formed as protrusion 8. Additionally, protrusion 8 can be formed into the shape extending upward in FIG. 16 from upper conductor layer 12, and a material with which bonding material 7a of the solder is hardly wettable may be used as protrusion 8. Electronic component 2 and thermal diffusion plate 31 are placed and bonded onto protrusion 8 formed on main surface 11a of printed board 1 so as to overlap protrusion 8.

An advantageous effect of the second embodiment will be described below. The second embodiment exerts the following advantageous effects in addition to the same effects as the first embodiment.

When protrusion 8 is formed as in semiconductor device 201, protrusion 8 prevents a defect that solder paste 6a (see FIG. 6) invades into the hole of first radiation via 15a. By forming protrusion 8, the interval between upper conductor layer 12 and heat radiation plate 24 and thermal diffusion plate 31 in the vertical direction of FIG. 16 is widened as compared with the case that protrusion 8 is not formed. In the region of the interval, the bonding material 7a in which solder paste 6a is melted is bonded to heat radiation plate 24 and thermal diffusion plate 31 while receiving stress so as to be pulled toward the upper side, namely, the sides of heat radiation plate 24 and thermal diffusion plate 31. For this reason, in the region between upper conductor layer 12 and heat radiation plate 24 and thermal diffusion plate 31, bonding material 7a flows into radiation via 15 to reduces a possibility that bonding material 7a flows on the inner wall surface of radiation via 15. As a result, the possibility that bonding material 7a short-circuits upper conductor layer 12 and cooling body 42 immediately below upper conductor layer 12 can be reduced to enhance reliability of entire semiconductor device 201.

Electronic component 2 and thermal diffusion plate 31 are placed so as to overlap protrusion 8 on upper conductor layer 12, which allows control of the interval of the region between upper conductor layer 12 and heat radiation plate 24 and thermal diffusion plate 31 in the vertical direction of FIG. 16. That is, the distance between electronic component 2 and thermal diffusion plate 31 that are bonded to printed board 1 and upper conductor layer 12 can be controlled by changing a printing position or a printing thickness of the solder resist or silk as protrusion 8. The thickness of bonding material 7a on upper conductor layer 12 can be controlled by protrusion 8, and quality of soldering with bonding material 7a can be improved. Bonding material 7a spreads in the region between upper conductor layer 12 and heat radiation plate 24 and thermal diffusion plate 31 along the main surface, bonding material 7a does not flow into the radiation via 15, and resultantly bonding material 7a does not reach the side of lower conductor layer 13. For this reason, the good fillet can be formed by bonding material 7a in the bonding portion between heat radiation plate 24 of electronic component 2 and thermal diffusion plate 31 of thermal diffuser 3 and printed board 1. As a result, whether the bonding state of bonding material 7a is good or bad can easily be determined by appearance inspection. In particular, in the case that electronic component 2 or the like is mounted by an automatic machine, the efficiency of the appearance inspection inspecting the mounting state can largely be improved.

When protrusion 8 of a small diameter resist is formed in a region adjacent to radiation vias 15 so as to surround radiation vias 15, protrusion 8 exerts a water repellent effect. This is because the resist is not wettable with the solder as compared with heat radiation plate 24, thermal diffusion plate 31, and upper conductor layer 12 that have good wettability to the solder as bonding material 7a. Because protrusion 8 surrounding radiation vias 15 is not wettable with the solder, the bonding material 7a that is the melted solder can be prevented from flowing into radiation vias 15 from main surface 11a to main surface 11b. Consequently, not only the short circuit caused by the solder can be prevented as described above, but also the hole as radiation via 15 remains to smoothly discharge a flux gas contained in bonding material 7a from radiation via 15 to the outside. For this reason, the remaining of a void due to the flux gas in bonding material 7a can be prevented.

Protrusion 8 may be formed not only adjacent to radiation via 15, but also at any position between heat radiation plate 24 and thermal diffusion plate 31 and upper conductor layer 12. Consequently, mounting heights of electronic component 2 and thermal diffuser 3 that are mounted on the printed board 1 with respect to printed board 1 can be kept constant. By providing protrusion 8 as a symbol mark at four corners of the region where electronic component 2 and thermal diffuser 3 are mounted at the transmission viewpoint from main surface 11a of printed board 1, electronic component 2 and thermal diffusion plate 31 can be disposed and mounted such that upper conductor layers 12 of printed board 1 are substantially parallel to the main surfaces of electronic component 2 and thermal diffusion plate 31.

### Third Embodiment

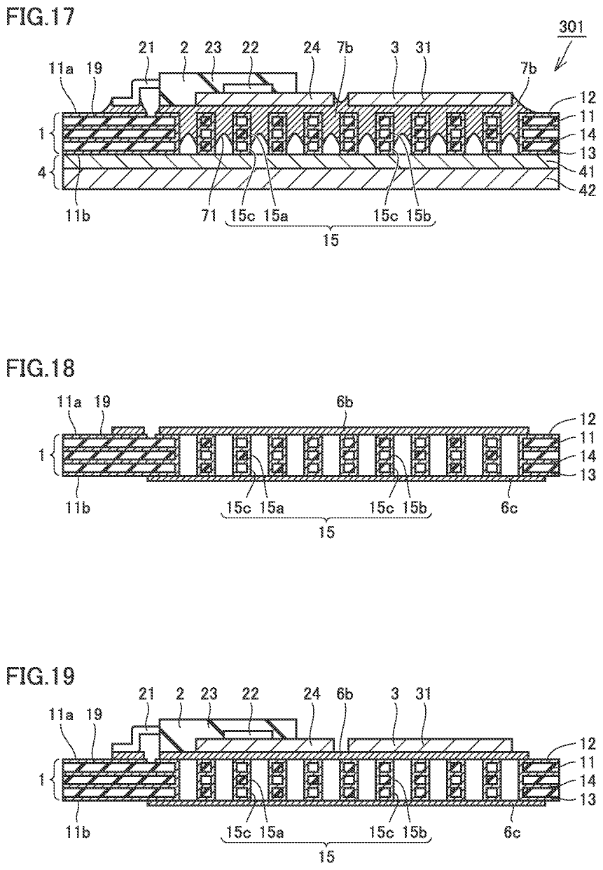

FIG. 17 is a schematic sectional view taken along a line A-A in FIG. 15 in a third embodiment. Referring to FIG. 17, because a semiconductor device 301 of the third embodiment basically has the same configuration as that of semiconductor device 101, the same component is designated by the same reference numeral, and the overlapping description will be omitted. However, in semiconductor device 301, bonding material 7a having a volume of greater than or equal to ⅓ of a volume of the inside of at least a part of the plurality of first radiation vias 15a overlapping electronic component 2 with conductor layers 12, 13, 14 interposed therebetween and second radiation vias 15b overlapping thermal diffusion plate 31 with conductor layers 12, 13, 14 interposed therebetween is disposed. However, bonding material 7a may be similarly disposed inside second radiation via 15b (see FIG. 15) that does not overlap any one of electronic component 2 and thermal diffusion plate 31. In this respect, semiconductor device 301 of the third embodiment is different from semiconductor device 101 in which the conductive material except for conductor film 15c on the inner wall surface is not disposed in the hole of first radiation via 15a or the like.

FIGS. 18 to 21 are schematic sectional views illustrating a mode in each process of manufacturing semiconductor device 301 of the third embodiment. With reference to FIGS. 18 to 21, an outline of a method for manufacturing semiconductor device 301, in particular, focusing on the process of mounting electronic component 2 and thermal diffuser 3 will be described below.

Referring to FIG. 18, a solder plate 6b is disposed on upper conductor layer 12 of printed board 1 while a flux removing an oxide film of the solder is interposed therebetween. Solder plate 6b becomes a mode in which radiation via 15 is covered from immediately above by the placement of solder plate 6b. A heat-resistant tape 6c made of polyimide is stuck to lower conductor layer 13 (the lower side in FIG. 18) in the first region of printed board 1 and a part of the second region. Heat-resistant tape 6c is stuck, in particular, so as to close the hole of radiation via 15 from the side of main surface 11b.

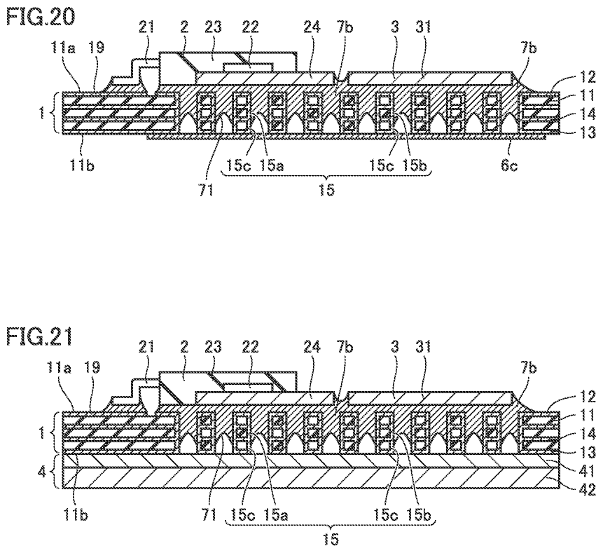

Referring to FIG. 19, electronic component 2 is mounted on solder plate 6b, and a known heating reflow process is performed. Consequently, referring to FIG. 20, solder plate 6b is melted to form bonding material 7b, and flows along the surface of upper conductor layer 12, whereby the inside of radiation via 15 is filled with bonding material 7b. This is because solder plate 6b is disposed so as to cover the hole of radiation via 15. Because heat-resistant tape 6c is stuck to lower conductor layer 13 in the first and second regions, melted solder plate 6b does not leak to the lower side of heat-resistant tape 6c, but radiation via 15 is filled with melted solder plate 6b.

Although the entire inside of radiation via 15 may be filled with bonding material 7a, preferably bonding material 7a having the volume of greater than or equal to ⅓ of the volume of the inside is disposed as illustrated in FIG. 20.

Referring to FIG. 21, heat-resistant tape 6c is removed after the solder in radiation via 15 is solidified. Thereafter, in the same manner as in the process of FIG. 8, for example, the heat radiation member 41 and the cooling body 42 are disposed in this order from the upper side to the lower side and in contact with each other so as to contact the lower conductor layer 13 of the printed board 1 Be done.

An advantageous effect of the second embodiment will be described below. The second embodiment exerts the following advantageous effects in addition to the same effects as the first embodiment.

An amount of heat transfer of the heat generated by electronic component 2 to the side of thermal diffusion plate 31 in the inside of first radiation via 15a and second radiation via 15b can be increased by disposing bonding material 7a in the inside of radiation via 15 as in semiconductor device 301. Because the conductive member such as solder has thermal conductivity higher than that of the hollow, the inside of first radiation via 15a or the like is filled with solder, and the area of the region having higher thermal conduction increases in section intersecting the extending direction of first radiation via 15a.

When solder plate 6b is melted prior to conductor film 15c on the inner wall surface of radiation via 15 in heating printed board 1 through the heating reflow process, the melted solder hardly flows along the inner wall surface of radiation via 15. As a result, the melted solder becomes massive solder to block radiation via 15, but a part of the region is not filled with the solder as illustrated in FIGS. 20, 21, and 17. When the amount of supplied solder is insufficient, a proportion of the solder disposed in radiation via 15 is reduced.

However, even in the modes of FIGS. 20, 21, and 17, in at least the portion of a massive solder 71 of bonding material 7a adjacent to upper conductor layer 12 and lower conductor layer 13, the section intersecting the extending direction of radiation via 15 is filled with massive solder 71, so that a proportion occupied by the solder having high thermal conductivity increases in the sectional area. Consequently, the heat radiation can be improved as compared with the case that radiation via 15 is not filled with the solder at all like semiconductor device 101. The effect that improves the heat radiation is sufficiently obtained when massive solder 71 extending from the side of upper conductor layer 12 has a height h greater than or equal to ⅓ of a length in the extending direction of radiation via 15. The same applies to the case that massive solder 71 extends only from one the side of upper conductor layer 12 and the side of lower conductor layer 13, or the case that massive solder 71 extends from both the side of upper conductor layer 12 and the side of lower conductor layer 13. That is, preferably the solder exists in the plurality of radiation vias 15 closed by at least one of the main surfaces (upper side) of thermal diffusion plate 31 such that the volume greater than or equal to ⅓ of the volume of radiation via 15 is filled with the solder.

In the second embodiment, protrusion 8 prevents bonding material 7a from flowing into radiation via 15, thereby reducing the possibility of short-circuiting upper conductor layer 12 and cooling body 42 immediately below upper conductor layer 12. On the other hand, in the third embodiment, bonding material 7a is caused to flow actively into radiation via 15. However, in the third embodiment, bonding material 7a flows into radiation via 15 in a state in which heat-resistant tape 6c is previously stuck so as to close the hole of radiation via 15 from the side of main surface 11b. Heat-resistant tape 6c is removed after the solder in radiation via 15 is solidified. Because heat-resistant tape 6c closes the holes to prevent bonding material 7a from flowing from radiation via 15 to the side of cooling body 42, the problem of the short circuit can be avoided even in the third embodiment.

### Fourth Embodiment

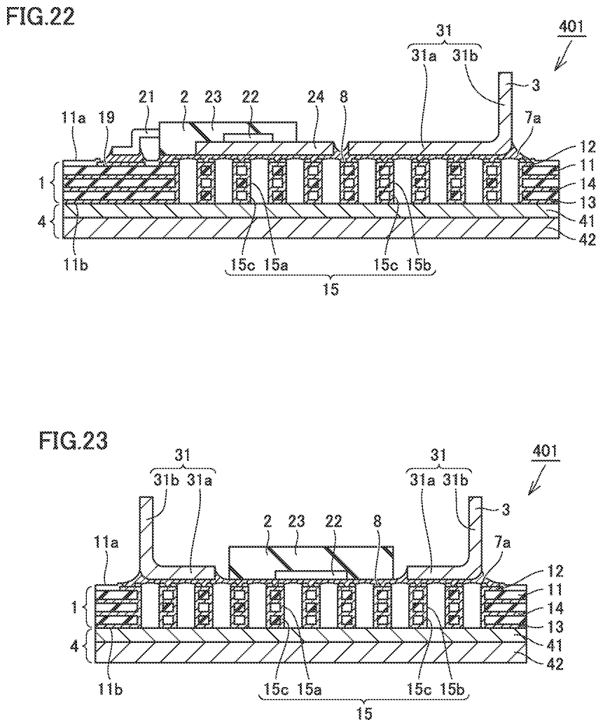

FIG. 22 is a schematic sectional view taken along the line A-A in FIG. 15 in a fourth embodiment. FIG. 23 is a schematic sectional view taken along a line B-B in FIG. 15 in the fourth embodiment. Referring to FIGS. 22 and 23, because a semiconductor device 401 of the fourth embodiment basically has the same configuration as that of semiconductor device 101, the same component is designated by the same reference numeral, and the overlapping description will be omitted. However, in semiconductor device 401, thermal diffusion plate 31 of the thermal diffuser 3 includes a first thermal diffusion plate 31a (first portion) and a second thermal diffusion plate 31b (second portion). First thermal diffusion plate 31a extends in the direction along main surface 11a of printed board 1, is bonded to main surface 11a, and extends in the left-right direction of FIGS. 22 and 23. Second thermal diffusion plat 31b is continuous to first thermal diffusion plate 31a, and extends in a direction intersecting first thermal diffusion plate 31a, namely, upward in FIGS. 22 and 23. Thus, second thermal diffusion plate 31b is not bonded to printed board 1.

In the sectional views of FIGS. 22 and 23, a boundary between first thermal diffusion plate 31a and second thermal diffusion plate 31b is bent such that the extending direction of the boundary changes by about 90°. However, the present invention is not limited to the fourth embodiment. For example, an angle formed between the extending directions of first thermal diffusion plate 31a and second thermal diffusion plate 31b may be less than 90° or more than 90°. That is, only a partial region of thermal diffusion plate 31 of semiconductor device 401 is bonded to main surface 11a. Semiconductor device 401 is different from semiconductor device 101, which does not have such two portions and is entirely bonded to main surface 11a of printed board 1, in this point.

Although protrusion 8 is provided in FIG. 22 and FIG. 23 as in the second embodiment, protrusion 8 may not be formed. The same applies to the following embodiments.

For example, thermal diffusion plate 31 of the fourth embodiment may be a heat sink to which a fin suitable for air cooling is attached. The heat sink is normally used along with a lead component such as TO-220 so as to extend in the vertical direction. However, in the fourth embodiment, the heat sink is used laterally so as to extend in the horizontal direction. When the widely-used heat sink is used as thermal diffusion plate 31, the manufacturing cost can be reduced.

An advantageous effect of the second embodiment will be described below. The second embodiment exerts the following advantageous effects in addition to the same effects as the first embodiment.

Thermal diffusion plate 31 includes second thermal diffusion plate 31b, thereby enhancing not only the heat diffusion effect but also the heat radiation effect. That is, first thermal diffusion plate 31a bonded to printed board 1 exerts the thermal diffusion effect, and second thermal diffusion plate 31b in which the entire surface touches with the outside air exerts the heat radiation effect. Thus, the effect that releases the heat generation of electronic component 2 to the outside can further be enhanced higher than the first embodiment and the like.

For example, when electronic component 2 is a switching element such as a MOSFET, a radiation noise is generated during switching, but the radiation noise to the outside can be reduced by second thermal diffusion plate 31b of thermal diffusion plate 31. For example, in the case that electronic component 2 is a control IC or an IC that processes a minute signal, there is an effect that reduces the radiation noise from the outside, and a malfunction of the IC can be prevented. Second thermal diffusion plate 31b of thermal diffusion plate 31 has a dustproof effect of dust and the like from the outside. Because second thermal diffusion plate 31b of thermal diffusion plate 31 absorbs the stress applied to printed board 1, the that printed board 1 is hardly warped is enhanced, and strength of printed board 1 is increased. Thermal diffusion plate 31 includes second thermal diffusion plate 31b, which allows a heat cycle property of bonding material 7a to be also enhanced, so that the reliability of semiconductor device 401 is improved.

### Fifth Embodiment

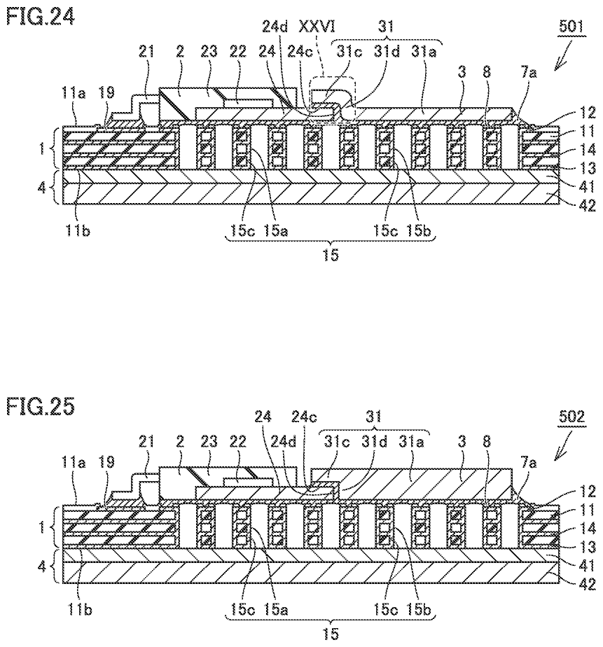

FIG. 24 is a schematic sectional view taken along the line A-A in FIG. 15 in a first example of a fifth embodiment. FIG. 25 is a schematic sectional view taken along the line A-A in FIG. 15 in a second example of the fifth embodiment. Referring to FIGS. 24 and 25, a semiconductor device 501 according to the first example of the fifth embodiment and a semiconductor device 502 according to the second example of the fifth embodiment have substantially the same configuration as semiconductor device 101, the same component is designated by the same reference numeral, and the overlapping description will be omitted. However, in semiconductor devices 501, 502, in particular heat radiation plate 24 of electronic component 2 includes a horizontally extending portion 24c (third portion) that is a portion (surface) extending in the left-right direction along main surface 11a of printed board 1 and a vertically extending portion 24d (fourth portion) which is a portion (surface) extending in the vertical direction intersecting main surface 11a. Thermal diffusion plate 31 is bonded to both at least a part of horizontally extending portion 24c and at least a part of vertically extending portion 24d by bonding material 7a.

That is, for example, in semiconductor device 501, thermal diffusion plate 31 includes three portions, i.e., first thermal diffusion plate 31a bonded to printed board 1 similarly to the fourth embodiment, a third thermal diffusion plate 31c that is a portion spreading in the direction along main surface 11a, and a fourth thermal diffusion plate 31d that is a portion spreading in the vertical direction intersecting main surface 11a. First thermal diffusion plate 31a, fourth thermal diffusion plate 31d, and third thermal diffusion plate 31c are sequentially extended from the right side to the left side of the drawing.

In semiconductor device 501, while first thermal diffusion plate 31a is bonded onto upper conductor layer 12, third thermal diffusion plate 31c and fourth thermal diffusion plate 31d are bent from first thermal diffusion plate 31a so as to ride on the surface of heat radiation plate 24. Third thermal diffusion plate 31c overlaps the horizontally extending portion 24c so as to be opposed to horizontally extending portion 24c in planar view, and fourth thermal diffusion plate 31d is disposed so as to be opposed to vertically extending portion 24d in planar view.

Semiconductor device 502 has almost the same configuration as semiconductor device 501, but semiconductor device 502 is slightly different from semiconductor device 501 in the sectional shape of thermal diffusion plate 31. Specifically, thermal diffusion plate 31 includes thermal diffusion plates 31a, 31c, 31d similarly to semiconductor device 501. First thermal diffusion plate 31a of semiconductor device 502 is bonded onto the upper conductor layer 12, but is slightly thicker than first thermal diffusion plate 31a of semiconductor device 501. Thermal diffusion plate 31 partially includes a notch on the left side of the drawing, and third thermal diffusion plate 31c and fourth thermal diffusion plate 31d are formed by the notch. At this point, a portion including the surface of the notch spreading along main surface 11a so as to be opposed to horizontally extending portion 24c is set to third thermal diffusion plate 31c, and a portion including the surface of the notch spreading along the direction intersecting main surface 11a so as to be opposed to vertically extending portion 24d is set to fourth thermal diffusion plate 31d. As a result, also in semiconductor device 502, third thermal diffusion plates 31c overlap horizontally extending portions 24c so as to ride on horizontally extending portions 24c.

As described above, in the fifth embodiment, heat radiation plate 24 of electronic component 2 and thermal diffusion plate 31 of thermal diffuser 3 are bonded in two surfaces. The fifth embodiment is different from semiconductor device 101 in that heat radiation plate 24 and thermal diffusion plate 31 are bonded in one surface. In the fifth embodiment, heat radiation plate 24 and thermal diffusion plate 31 may be bonded in at least three surfaces.

In the manufacturing method of the fifth embodiment, for example, the shape of thermal diffusion plate 31 in semiconductor device 501 can be formed at low manufacturing cost by pressing a copper plate in a known manner. For example, the shape of thermal diffusion plate 31 in semiconductor device 502 can be obtained by forming the notch by known cutting or extruding of a copper plate. In this case, the thermal resistance between electronic component 2 and thermal diffusion plate 31 can be reduced, and the thermal diffusion efficiency of thermal diffusion plate 31 can further be enhanced.

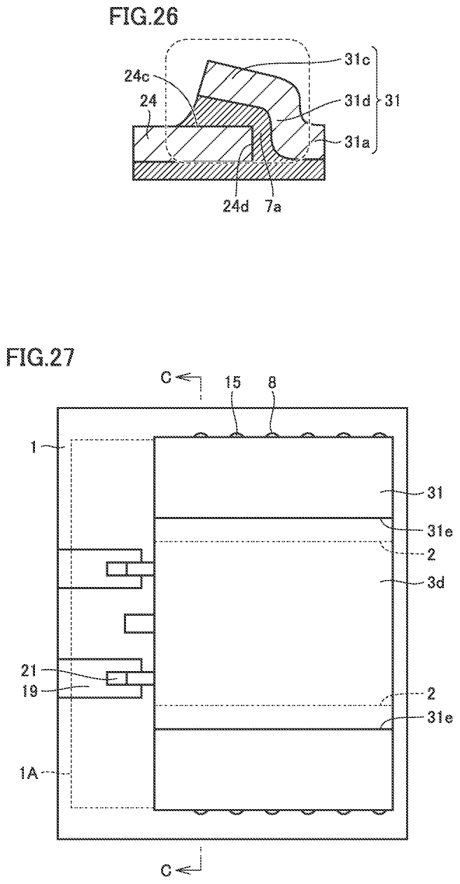

With reference to FIG. 26, the advantageous effect of the fifth embodiment will be described below. The second embodiment exerts the following advantageous effects in addition to the same effects as the first embodiment.

In the configuration of the fifth embodiment, a bonding heat resistance between heat radiation plate 24 and thermal diffusion plate 31 can be decreased, and the heat diffusion effect is enhanced. With the above configuration, the stress applied to printed board 1 is easily absorbed, and printed board 1 is hardly warped, so that the strength of printed board 1 is increased. Because the heat cycle property of bonding material 7a can also be enhanced, the reliability of the semiconductor device 401 is enhanced.

In FIG. 24, the extending direction is bent such that extending direction is changed by about 90° at the boundary between first thermal diffusion plate 31a and fourth thermal diffusion plate 31d and the boundary between fourth thermal diffusion plate 31d and third thermal diffusion plate 31c. However, the present invention is not limited to the fifth embodiment, but the angle formed by the extending directions of two portions sandwiched between the boundaries may be less than 90° or more than 90°. For example, FIG. 26 illustrates a more preferable mode of a region XXVI surrounded by a dotted line in FIG. 24. Referring to FIG. 26, the angle formed between third thermal diffusion plate 31c and fourth thermal diffusion plate 31d exceeds 90°. As a result, the air in the region between third thermal diffusion plate 31c and horizontally extending portion 24c is easily released. Consequently, an air layer between third thermal diffusion plate 31c and horizontally extending portion 24c becomes thinner and the thermal conductivity between third thermal diffusion plate 31c and horizontally extending portion 24c becomes higher. From the viewpoint of facilitating the release of the air in the region between third thermal diffusion plate 31c and horizontally extending portion 24c, preferably third thermal diffusion plate 31c and horizontally extending portion 24c are brought close to each other as much as possible, or the extending direction of third thermal diffusion plate 31c is inclined with respect to the direction along main surfaces 11a.

### Sixth Embodiment

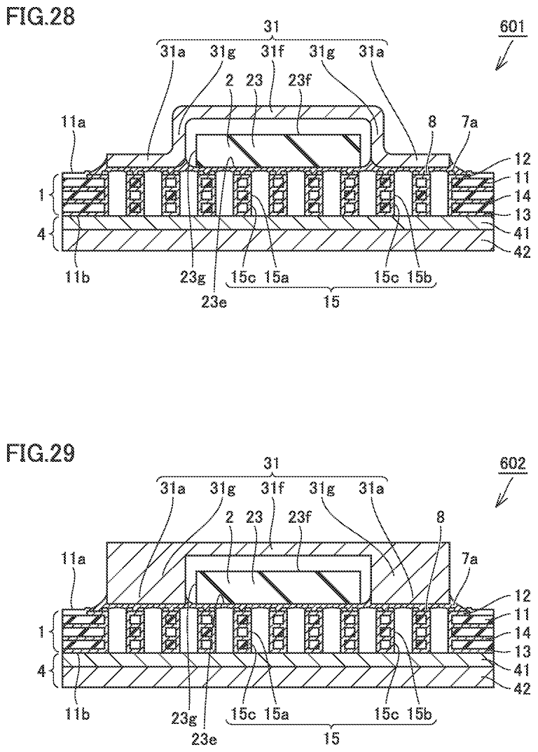

FIG. 27 collectively illustrates a mode of a whole or a part of a semiconductor device of each example of a sixth embodiment at a transmissive viewpoint from above, namely, in planar view from above. FIG. 28 is a schematic sectional view taken along a line C-C in FIG. 27 in a first example of the sixth embodiment. FIG. 29 is a schematic sectional view taken along the line C-C of FIG. 27 in a second example of the sixth embodiment. FIGS. 28 and 29 are schematic sectional views seen from the direction corresponding to the line B-B in FIG. 15. Referring to FIGS. 27, 28, and 29, a semiconductor device 601 of the first example of the sixth embodiment and a semiconductor device 602 of the second example of the sixth embodiment have substantially the same configuration as semiconductor device 101, the same component is designated by the same reference numeral, and the overlapping description will be omitted. However, a downward mold surface 23e (first surface) in which resin mold 23 of electronic component 2 is opposed to main surface 11a of printed board 1 and an upward mold surface 23f (second surface) on the opposite side are considered in semiconductor devices 601, 602. At this point, a part of thermal diffusion plate 31 is disposed so as to cover upward mold surface 23f.

That is, for example, in semiconductor device 601, thermal diffusion plate 31 includes first thermal diffusion plate 31a bonded to printed board 1 similarly to the fourth and fifth embodiments, a fifth thermal diffusion plate 31f that is a portion spreading in the direction along main surface 11a, and a sixth thermal diffusion plate 31g that is a portion spreading in the vertical direction intersecting main surface 11a. First thermal diffusion plate 31a, sixth thermal diffusion plate 31g, fifth thermal diffusion plate 31f, sixth thermal diffusion plate 31g, and first thermal diffusion plate 31a are extended from the left side to the right side of the drawing.

In the semiconductor device 601, while first thermal diffusion plate 31a is bonded onto upper conductor layer 12, fifth thermal diffusion plate 31f and sixth thermal diffusion plate 31g are bend from first thermal diffusion plate 31a so as to straddle resin mold 23 from the upper side. Fifth thermal diffusion plate 31f overlaps upward mold surface 23f so as to be opposed to upward mold surface 23f in planar view, and sixth thermal diffusion plate 31g is disposed so as to be opposed to a mold side surface 23g of resin mold 23.

Semiconductor device 602 has almost the same configuration as semiconductor device 601, but semiconductor device 602 is slightly different from semiconductor device 601 in the sectional shape of thermal diffusion plate 31. Specifically, thermal diffusion plate 31 includes thermal diffusion plates 31a, 31g, 31f similarly to semiconductor device 601. In semiconductor device 602, first thermal diffusion plate 31a bonded to main surface 11a extends immediately above, and the portion extending immediately above constitutes sixth thermal diffusion plate 31g, and is opposed to mold side surface 23g. In this case, the portion expanding in the direction intersecting main surface 11a so as to be opposed to mold side surface 23g is set to sixth thermal diffusion plate 31g, and the region bonded to lowermost printed board 1 of sixth thermal diffusion plate 31g is set to first thermal diffusion plate 31a. As a result, even in semiconductor device 602, fifth thermal diffusion plate 31f and sixth thermal diffusion plate 31g have the shape that is bent so as to straddle resin mold 23.

As described above, in the sixth embodiment, thermal diffusion plate 31 is bonded to printed board 1 so as to straddle electronic component 2. Thermal diffusion plate 31 includes the region that is disposed so as to cover and overlap the top surface of electronic component 2. The sixth embodiment is different from semiconductor device 101, which does not have the configuration, in this point. Fifth thermal diffusion plate 31f of thermal diffusion plate 31 and the upward mold surface 23f may be bonded together.

In the manufacturing method of the sixth embodiment, the shape of thermal diffusion plate 31 in semiconductor device 601 can be formed in the same manner as semiconductor device 501. The shape of thermal diffusion plate 31 in semiconductor device 602 can be formed in the same manner as semiconductor device 502.

The advantageous effects of the sixth embodiment are as follows. As thermal diffusion plate 31 includes thermal diffusion plates 31f, 31g as in the sixth embodiment, the same effects as the fourth embodiment can be obtained in addition to the same effects as the first embodiment. For this reason, the detailed description thereof will not be repeated. In FIGS. 28 and 29, the air layer is provided between thermal diffusion plate 31 and resin mold 23. However, in the case that the air layer does not exist but thermal diffusion plate 31 and resin mold 23 are bonded together, the thermal conductivity between thermal diffusion plate 31 and resin mold 23 becomes higher.

### Seventh Embodiment

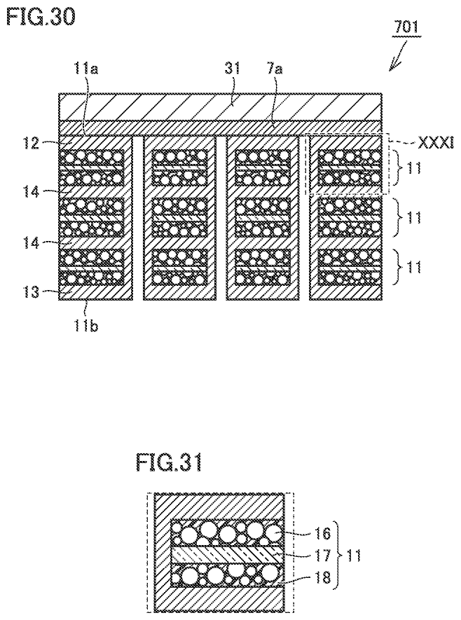

FIG. 30 is an enlarged view illustrating a semiconductor device according to a seventh embodiment, in particular, a partial region of printed board 1. FIG. 31 is an enlarged view illustrating a region XXXI surrounded by a dotted line in FIG. 30, namely, the mode of insulating layer 11. Referring to FIGS. 30 and 31, because a semiconductor device 701 of the fourth embodiment basically has the same configuration as that of semiconductor device 101, the same component is designated by the same reference numeral, and the overlapping description will be omitted. However, semiconductor device 701 is different from semiconductor device 101 in that insulating layer 11 of printed board 1 includes filler 16. As illustrated in FIG. 31, insulating layer 11 includes glass fiber 17 and epoxy resin 18.

Filler 16 is an inorganic filler particle, and preferably an aluminum oxide particle is used as filler 16. However, the present invention is not limited thereto, but ceramic particles such as aluminum nitride or boron nitride may be used. Filler 16 may have a configuration in which several kinds of particles are mixed, and for example, aluminum hydroxide may be mixed with aluminum oxide.

That is, in semiconductor device 701, each of the plurality of insulating layers 11 included in printed board 1 includes inorganic filler particles. Consequently, the thermal conductivity and a heat-resisting property of insulating layer 11 can be improved. When containing filler 16 as the inorganic filler particle, insulating layer 11 can conduct the heat through filler 16. Consequently, the thermal conduction of insulating layer 11 can be increased, and the thermal resistance of printed board 1 can be decreased.

Using the equation (1) and a model similar to that of the first embodiment, the thermal resistance value was simulated with respect to semiconductor device 701 including printed board 1 constructed with insulating layer 11 including 70 wt % of filler 16 made of aluminum oxide. Except for the existence of filler 16, the model has the same size and configuration as those of semiconductor device 101 of the first embodiment. As a result, it was found that the thermal resistance value can be further reduced by about 5% as compared with semiconductor device 101 in FIG. 11.

In the seventh embodiment, in order to increase the radiation effect, it is necessary to increase packing density of filler 16 included in insulating layer 11. Specifically, preferably the packing density of filler 16 is increased up to 80 wt %. For this reason, the shape of filler 16 is not limited to a spherical shape as illustrated in FIG. 13(B), but may be a three-dimensional shape based on a polygon such as a tetrahedron or a hexagonal crystal.

In the seventh embodiment, the size of filler 16 with which insulating layer 11 is filled is not necessarily kept constant. That is, even if only the particles of a single kind of filler 16 are included in insulating layer 11, filler 16 may be formed by mixing particles of several sizes. In this case, because small-size filler 16 enters the region sandwiched between the plurality of large-size fillers 16, insulating layer 11 can be filled with filler 16 with higher density. Consequently, the heat radiation of insulating layer 11 can further be improved.

### Eighth Embodiment

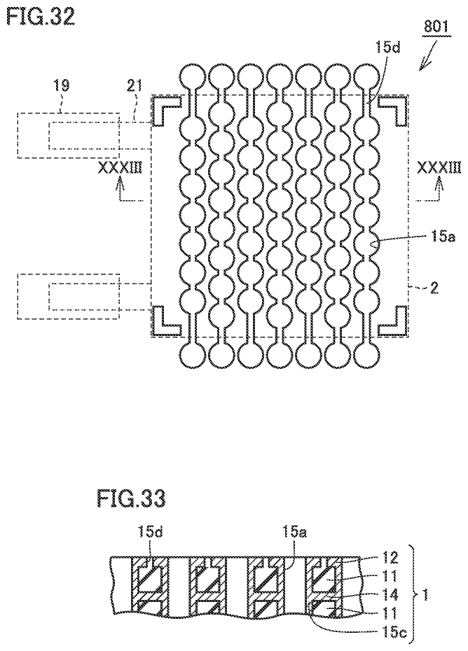

FIG. 32 is an enlarged plan view illustrating a semiconductor device according to an eighth embodiment, in particular, the region of first radiation via 15a. FIG. 33 is a schematic sectional view taken along a line XXXIII-XXXIII in FIG. 32. Referring to FIGS. 32 and 33, because a semiconductor device 801 of the eighth embodiment basically has the same configuration as that of semiconductor device 101, the same component is designated by the same reference numeral, and the overlapping description will be omitted. However, in semiconductor device 801, in the region sandwiched between a plurality (in particular, one pair) of adjacent first radiation vias 15a in upper conductor layer 12, groove 15d is formed so as to connect the holes of first radiation vias 15a. Semiconductor device 801 is different from semiconductor device 101, in which groove 15d is not formed, in this point.

Although groove 15d is formed only in the first region in FIGS. 32 and 33, the present invention is not limited to the eighth embodiment. Alternatively, groove 15d may be formed so as to connect the holes of the radiation vias 15 adjacent to each other in the second region. In other words, groove 15d that connect the radiation vias 15 adjacent to each other at the transmission viewpoint from main surface 11a of printed board 1 in the plurality of radiation vias 15 is formed in printed board 1 of semiconductor device 801.

Groove 15d can be formed by an ordinary photolithography technique and etching when upper conductor layer 12 of printed board 1 is patterned.

In semiconductor device 801, the provision of groove 15d can release the air, which is expanded in first radiation via 15a due the heating for melting the solder during manufacturing, to the outside through groove 15d. Consequently, first radiation via 15a can easily be filled with the solder by preventing an increase in pressure of first radiation via 15a.

### Ninth Embodiment

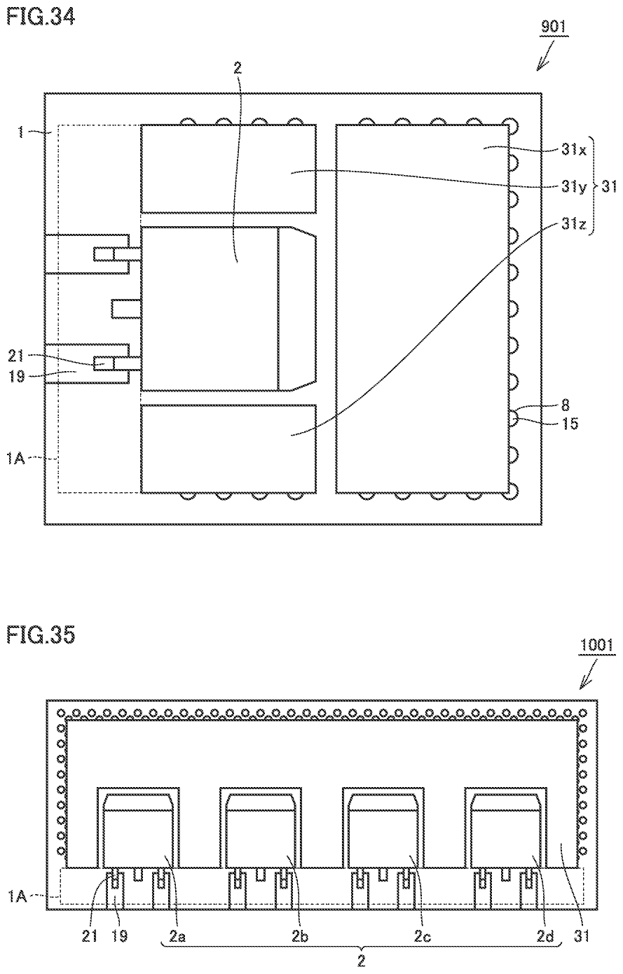

FIG. 34 illustrates a mode of a whole or a part of a semiconductor device according to a ninth embodiment at the transmission viewpoint from above. Referring to FIG. 34, because a semiconductor device 901 of the ninth embodiment basically has the same configuration as that of semiconductor device 101, the same component is designated by the same reference numeral, and the overlapping description will be omitted. However, in semiconductor device 901, thermal diffusion plate 31 disposed around electronic component 2 at the transmission viewpoint from main surface 11a of printed board 1 is divided into three thermal diffusion plates 31x, 31y, 31z. Preferably thermal diffusion plates 31x, 31y, 31z are disposed spaced apart from each other, but the present invention is not limited to the eighth embodiment. Semiconductor device 901 is different from semiconductor device 101, in which thermal diffusion plate 31 is disposed as a single component on three sides of the periphery of electronic component 2, in this point.

In FIG. 34, as an example, thermal diffusion plate 31 is divided into three regions separated from each other. However, thermal diffusion plate 31 may be divided into any number of the plurality of regions other than three, for example, two or four. Each of the plurality of thermal diffusion plates 31x, 31y, 31z is bonded to electronic component 2 by the solder that is bonding material 7a.

For example, when the size of each of thermal diffusion plates 31x, 31y, 31z is increased as in thermal diffusion plate 31 of semiconductor device 101, thermal diffusion plate 31 is hardly mounted using the mounter. When thermal diffusion plate 31 has a rectangular or square planar shape in which a center and a center of gravity are the same point, a proportion defective of the mounting process with the mounter decreases as compared with the case that thermal diffusion plate 31 has an asymmetric planar shape. For this reason, thermal diffusion plate 31 is divided into a plurality of rectangles as in the ninth embodiment, which allows thermal diffusion plate 31 to be easily mounted with the mounter to reduce the mounting cost. That is, in the ninth embodiment, thermal diffusion plate 31 can be formed into a mode suitable for the automatic mounting.

### Tenth Embodiment

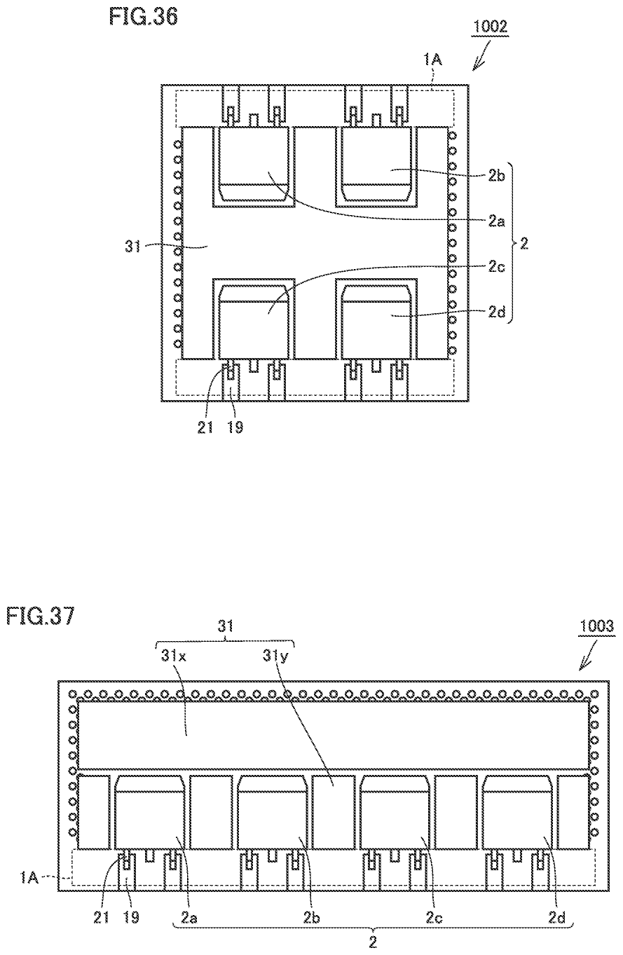

FIG. 35 illustrates a mode of a whole or a part of a semiconductor device according to a first example of a tenth embodiment at the transmission viewpoint from above. FIG. 36 illustrates a mode of a whole or a part of a semiconductor device according to a second example of the tenth embodiment at the transmission viewpoint from above. Referring to FIGS. 35 and 36, a semiconductor device 1001 of the first example of the tenth embodiment and a semiconductor device 1002 of the second example of the tenth embodiment have substantially the same configuration as semiconductor device 101, the same component is designated by the same reference numeral, and the overlapping description will be omitted. However, in each of semiconductor devices 1001, 1002, electronic component 2 is disposed as four electronic components 2a, 2b, 2c, 2d at a distance from one another in the transmission viewpoint from main surface 11a of printed board 1. In semiconductor device 1001, four electronic components 2a to 2d are arranged in a line in the left-right direction of the drawing. On the other hand, in semiconductor device 1002, four electronic components 2a to 2d are arranged in a matrix form in which two rows are arranged in the left-right direction of the drawing while two columns are arranged in the vertical direction of the drawing.

As described above, in the semiconductor device of the tenth embodiment, the plurality of electronic components 2 are arranged at intervals. The tenth embodiment differs from semiconductor device 101, in which only single electronic component 2 is disposed, in this point. The number of electronic components 2 is not limited to four as illustrated in semiconductor devices 1001, 1002, but may be any plural number. Thermal diffusion plate 31 connected as a single thermal diffuser 3 is disposed around each of the plurality of electronic components 2a to 2d in planar view.

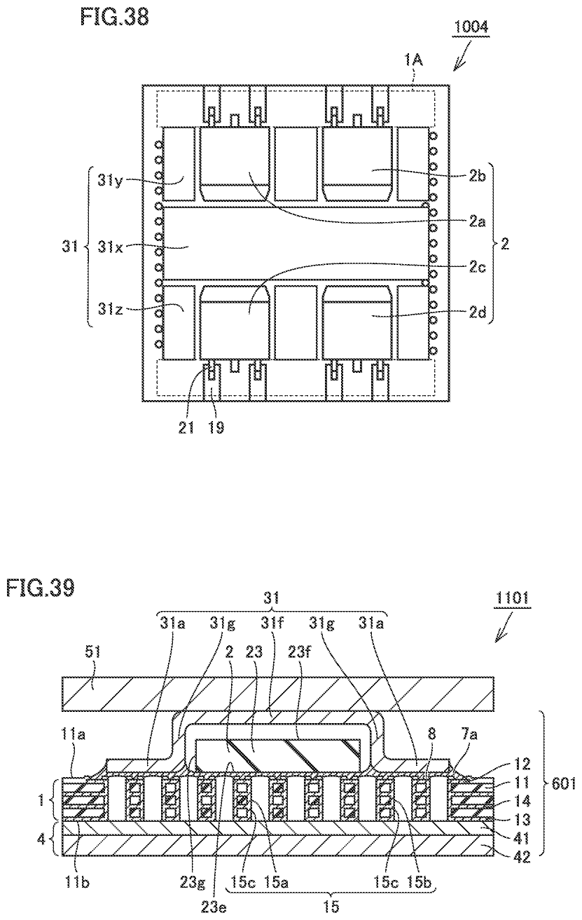

With reference to FIGS. 37 and 38 that are comparative examples, the advantageous effect of the tenth embodiment will be described below.

FIG. 37 illustrates a mode of a whole or a part of a semiconductor device of the comparative example corresponding to the first example of the tenth embodiment at the transmission viewpoint from above. FIG. 38 illustrates a mode of a whole or a part of a semiconductor device of the comparative example corresponding to the second example of the eleventh embodiment at the transmission viewpoint from above. Referring to FIGS. 37 and 38, semiconductor device 1003 and semiconductor device 1004 basically have the same configuration as that of semiconductor devices 1001 1002, the same component is designated by the same reference numeral, and the overlapping description will be omitted.

However, in semiconductor devices 1003, 1004, similarly to semiconductor device 901 of the ninth embodiment, thermal diffusion plate 31 is divided into a plurality of thermal diffusion plates. Specifically, in FIG. 37, thermal diffusion plate 31 is divided into thermal diffusion plate 31x on the upper side of electronic component 2 and five thermal diffusion plates 31y sandwiched between electronic components 2a to 2d (adjacent to electronic components 2a, 2d) in the right-left direction of the drawing. In FIG. 38, thermal diffusion plate 31 is divided into thermal diffusion plate 31x spreading to the central portion in the vertical direction of the drawing, three thermal diffusion plates 31y adjacent to electronic components 2a, 2b in the upper region of thermal diffusion plate 31x, and three thermal diffusion plates 31z adjacent to electronic components 2c, 2d in the lower region of thermal diffusion plate 31x.

For example, in the case that the plurality of electronic components 2 are connected in parallel in one semiconductor device as illustrated in FIG. 38, the heating value may also vary due to the variation in the internal resistance of electronic components 2 or the like. In the case that four thermal diffusion plates are disposed in a plurality of, for example, four electronic components 2a to 2d during the parallel connection, there is a possibility that the electronic component having the large heating value further increases the heating value due to own heat generation to cause thermal runaway. The same applies to the case that the plurality of electronic components 2 are connected in parallel in one semiconductor device as illustrated in FIG. 37.

However, the temperatures of electronic components 2a to 2d are balanced by disposing only single thermal diffusion plate 31 of the plurality of electronic components 2a to 2d as in the tenth embodiment, and the high-reliability semiconductor device in which the thermal runaway is hardly generated can be provided. This is attributed to the following fact. That is, the plurality of electronic components 2a to 2d are disposed while only one thermal diffusion plate 31 is disposed, which allows the heat to be uniformly radiated from each of the plurality of electronic components 2a to 2d to identical thermal diffusion plate 31 as compared with the case that the plurality of thermal diffusion plates are disposed in the plurality of electronic components 2a to 2d, respectively.

### Eleventh Embodiment

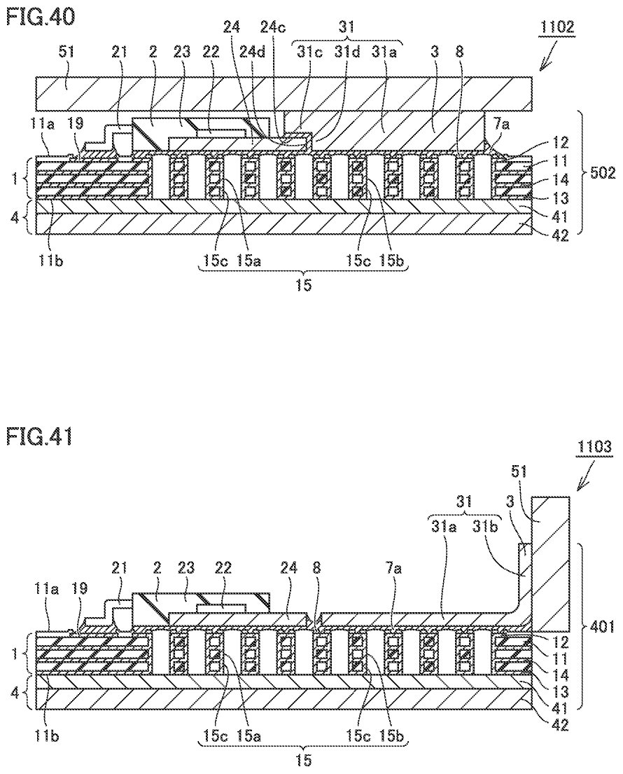

FIG. 39 is a schematic sectional view taken along the line C-C in FIG. 27 in a first example of an eleventh embodiment. FIG. 40 is a schematic sectional view taken along the line A-A in FIG. 15 in a second example of the eleventh embodiment. FIG. 41 is a schematic sectional view taken along the line A-A in FIG. 15 in a third example of the eleventh embodiment.

Referring to FIG. 39, in a semiconductor device 1101 of the first example of the eleventh embodiment, a casing 51 is disposed so as to be in close contact with fifth thermal diffusion plate 31f of thermal diffusion plate 31 in semiconductor device 601 of the sixth embodiment. Referring to FIG. 40, in a semiconductor device 1102 of the second example of the eleventh embodiment, casing 51 is disposed so as to be in close contact with third thermal diffusion plate 31c and fourth thermal diffusion plate 31d of thermal diffusion plate 31 in semiconductor device 502 of the fifth embodiment. Referring to FIG. 41, in a semiconductor device 1103 of the third example of the eleventh embodiment, casing 51 is disposed so as to be in close contact with second thermal diffusion plate 31b of thermal diffusion plate 31 in semiconductor device 401 of the fourth embodiment. The eleventh embodiment is different from semiconductor devices 601, 502, 401 in that casing 51 is disposed, but the eleventh embodiment is basically identical to semiconductor devices 601, 502, 401 in other points. For this reason, the same component as that of semiconductor devices 601, 502, 401 is designated by the same reference numeral, and the overlapping description will be omitted.

Casing 51 is a member protecting entire semiconductor devices 1101 to 1103 from the outside, and FIGS. 39 to 41 illustrate a part of casing 51, for example, a portion having a flat plate shape. Preferably casing 51 is made of aluminum. Aluminum can transfer the heat inside the semiconductor device to the outside, and aluminum is lighter than copper and the like. Casing 51 may be made of a good-thermal-conductivity ceramic material, such as aluminum oxide or aluminum nitride, in which a metal film such as copper is formed in the surface. Casing 51 may be made of a metal material in which a nickel plating film and a gold plating film are formed on the surface of any alloy material selected from a group consisting of a copper alloy, an aluminum alloy, and a magnesium alloy. When the material having the good thermal conductivity is used as casing 51, the thermal conductivity (heat radiation) of semiconductor devices 1101 to 1103 can be enhanced.

In the same manner as described above, casing 51 may be disposed so as to be in close contact with thermal diffusion plate 31 of the semiconductor device of each embodiment (examples) that is not described here.

The eleventh embodiment has a route in which the heat is radiated from thermal diffusion plate 31 to the outside through casing 51 in addition to the route of the first embodiment in which the heat generated by electronic component 2 is radiated from thermal diffusion plate 31 in FIG. 10 to the side of heat radiator 4 through second radiation via 15b. Consequently, semiconductor devices 1101 to 1103 having the excellent heat radiation as compared with the configuration that does not include casing 51 can be provided.

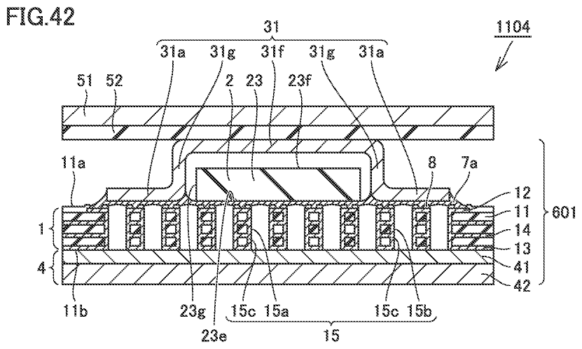

FIG. 42 is a schematic sectional view taken along the line C-C in FIG. 27 in a fourth example of the eleventh embodiment. Referring to FIG. 42, in a semiconductor device 1104 of the fourth example of the eleventh embodiment, heat radiation member 52 is sandwiched between thermal diffusion plate 31 (fifth thermal diffusion plate 310 of semiconductor device 1101 and casing 51, and heat radiation member 52 is disposed so as to be in close contact with both thermal diffusion plate 31 and casing 51. Preferably heat radiation member 52 is a sheet-shaped member made of the same material as heat radiation member 41. Semiconductor device 1104 differs from semiconductor device 1101, which does not include heat radiation member 52, in this point, but semiconductor device 1104 is basically identical to semiconductor device 1101 in other points. For this reason, the same component as that of semiconductor device 1101 is designated by the same reference numeral, and the overlapping description will be omitted. When the potentials of thermal diffusion plate 31 and casing 51 are different from each other, preferably heat radiation member 52 having electric insulation is sandwiched between thermal diffusion plate 31 and casing 51. Consequently, the heat generated from electronic component 2 can more efficiently be radiated from thermal diffusion plate 31 and casing 51 to the outside while the short circuit between thermal diffusion plate 31 and casing 51 is prevented.

### Twelfth Embodiment

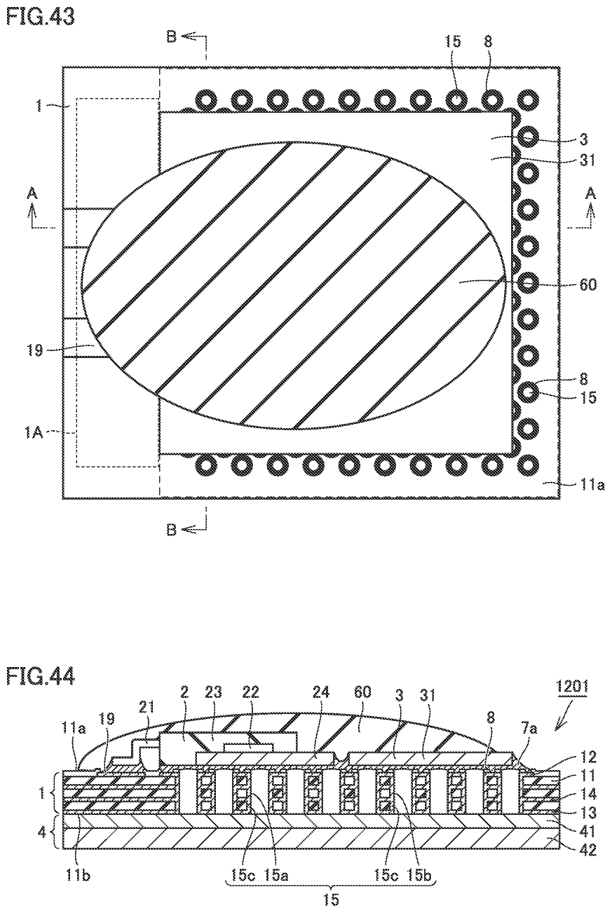

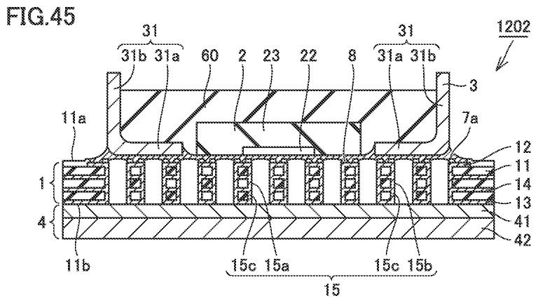

FIG. 43 is a schematic plan view illustrating a semiconductor device according to each example of a twelfth embodiment. FIG. 44 is a schematic sectional view taken along a line A-A in FIG. 43 in a first example of the twelfth embodiment. FIG. 45 is a schematic sectional view taken along a line B-B in FIG. 43 in the second example of the twelfth embodiment. Referring to FIGS. 43 and 44, because a semiconductor device 1201 basically has the same configuration as the configuration in FIGS. 15 and 16, the same component is designated by the same reference numeral, and the overlapping description will be omitted. However, semiconductor device 1201 includes a thermal diffusion material 60 that covers at least a part of electronic component 2 and thermal diffuser 3.

Preferably, a material having an excellent electrical characteristic and an excellent mechanical characteristic, high thermal conductivity, and the excellent heat radiation in the portion having the high heating value is used as thermal diffusion material 60. Preferably thermal diffusion material 60 is a material having a low thermal expansion coefficient, excellent crack resistance, low viscosity, and good workability. Preferably heat diffusion material 60 is a material that reduces a warpage amount of printed board 1 or the like by decreasing the stress during heat curing. Preferably heat diffusion material 60 is a material having a small amount of weight loss under high temperature storage and excellent heat resistance. Preferably heat diffusion material 60 is a material having low impurity ion concentration and excellent reliability. From the above viewpoint, an epoxy resin potting material is used as a representative example of thermal diffusion material 60. However, thermal diffusion material 60 may be any one selected from a group consisting of an acrylic resin, silicon, urethane, polyurethane, an epoxy resin, and fluorine. Any one of grease, an adhesive, and a heat radiation sheet may be used as the heat diffusion material 60 instead of each of the above materials. However, thermal diffusion material 60 is not limited to the above materials.

Referring to FIG. 45, because a semiconductor device 1202 of the second example of the twelfth embodiment basically has the same configuration as semiconductor device 401 in FIG. 23, the same component is designated by the same reference numeral, and the overlapping description will be omitted. However, in semiconductor device 1202, thermal diffusion material 60 is provided so as to cover at least a part of electronic component 2 and thermal diffuser 3.

In FIG. 45, the region surrounded by second thermal diffusion plate 31b of thermal diffusion plate 31 is filled with thermal diffusion material 60. In other words, thermal diffusion material 60 is formed so as to cover first thermal diffusion plate 31a and electronic component 2.

The advantageous effect of the twelfth embodiment will be described below. In the twelfth embodiment, at least a part of electronic component 2 and thermal diffuser 3 is covered with thermal diffusion material 60. Consequently, the heat generated from electronic component 2 can more efficiently be transmitted to thermal diffuser 3. The heat radiation by thermal diffusion material 60 can be improved. The effect that enhances the insulation, moisture resistance, waterproofness, chlorine resistance, and oil resistance to the outside of printed board 1 and electronic component 2 that are covered with thermal diffusion material 60 can be obtained. A foreign matter can be prevented from being mixed in printed board 1 and electronic component 2 that are covered with thermal diffusion material 60.

In the configuration of FIG. 45, thermal diffusion plate 31 includes first thermal diffusion plate 31a and second thermal diffusion plate 31b in which the extending direction is different from that of first thermal diffusion plate 31a by about 90°. For this reason, thermal diffusion material 60 can be prevented from flowing to the region to which thermal diffusion material 60 is not desired to be supplied. In FIG. 45, a part or a whole of electronic component 2 can be covered with thermal diffusion material 60 in a minimal amount. As described above, in FIG. 45, electronic component 2 can be covered with thermal diffusion material 60 by utilizing the feature of the shape of thermal diffusion plate 31. Consequently, the high heat radiation can be obtained at low cost.

The example that introduces thermal diffusion material 60 to the configurations of the second and fourth embodiments is illustrated as an example. However, thermal diffusion material 60 can be used for any one of the first to eleventh embodiments.

The features described in the above embodiments (examples included in the embodiments) may appropriately be combined within a range where technical contradiction is not generated.

It should be considered that the disclosed embodiments are an example in all respects and not restrictive. The scope of the present invention is defined by not the description above, but the claims, and it is intended that all modifications within the meaning and scope of the claims are included in the present invention.

### REFERENCE SIGNS LIST

1: printed board, 1A: region, 2: electronic component, 3: thermal diffuser, 4: heat radiator, 51: casing, 6a: solder paste, 6b: solder plate, 6c: heat-resistant tape, 7a, 7b: bonding material, 8: protrusion, 11: insulating layer, 11a: one of main surfaces, 11b: the other main surface, 12: upper conductor layer, 13: lower conductor layer, 14: inner conductor layer, 15: radiation via, 15a: first radiation via, 15b: second radiation via, 15c: conductor film, 15d: groove, 16: filler, 17: glass fiber, 18: epoxy resin, 21: lead terminal, 22: semiconductor chip, 23: resin mold, 23e: downward mold surface, 23f: upward mold surface, 23g: mold side surface, 24: heat radiation plate, 24c: horizontally extending portion, 24d: vertically extending portion, 31, 31x, 31y, 31z: thermal diffusion plate, 31a: first thermal diffusion plate, 31b: second thermal diffusion plate, 31c: third thermal diffusion plate, 31d: fourth thermal diffusion plate, 31f: fifth thermal diffusion plate, 31g: sixth thermal diffusion plate, 41, 52: heat radiation member, 42: cooling body, 60: thermal diffusion material, 71: massive solder, 101, 102, 201, 301, 401, 501, 502, 601, 602, 701, 801, 901, 1001, 1002, 1101, 1102, 1103, 1104, 1201, 1202: semiconductor device, H1, H2: heat

1. A semiconductor device comprising:
a printed board; and
an electronic component and a thermal diffuser that are bonded onto one of main surfaces of the printed board, wherein
the electronic component and the thermal diffuser are electrically and thermally connected to each other by a bonding material,
the printed board includes an insulating layer, a plurality of conductor layers each of which is disposed on one and another of main surfaces of the insulating layer, and a plurality of radiation vias penetrating from one of the main surfaces to the other main surface of the insulating layer, and
at least a part of the plurality of radiation vias overlaps the electronic component at a transmission viewpoint from one of the main surfaces of the printed board, at least another part of the plurality of radiation vias overlaps the thermal diffuser at the transmission viewpoint from one of the main surfaces of the printed board, and at least a part of the plurality of radiation vias is disposed so as to overlap a heat radiator at a transmission viewpoint from the other main surface of the printed board,
the electronic component includes a lead terminal, a semiconductor, a mold, and a heat radiation plate,
the heat radiation plate is disposed between the semiconductor and the printed board,
the heat radiation plate and the thermal diffuser are electrically and thermally connected to each other by bonding material.

2. The semiconductor device according to claim 1, wherein
a protrusion is disposed on one of the main surfaces of the printed board, and
the electronic component and the thermal diffuser are disposed so as to overlap the protrusion at the transmission viewpoint from one of the main surfaces of the printed board,
the bonding material is disposed between the protrusion and the heat radiation plate or the thermal diffuser.

3. The semiconductor device according to claim 1, wherein inside at least a part of the plurality of radiation vias overlapping the electronic component or the thermal diffuser with the plurality of conductor layers interposed therebetween, the bonding material for a volume greater than or equal to ⅓ of a volume of the inside is disposed.

4. The semiconductor device according to claim 1, wherein the thermal diffuser includes a first portion that extends in a direction along one of the main surfaces of the printed board and is bonded to one of the main surfaces of the printed board, and a second portion extending in a direction intersecting the first portion.

5. The semiconductor device according to claim 1, wherein the thermal diffuser is bonded to both at least a part of a third portion extending in a direction along one of main surfaces of the electronic component and at least a part of a fourth portion extending in a direction intersecting one of the main surfaces of the electronic component, by the bonding material.

6. The semiconductor device according to claim 1, wherein a part of the thermal diffuser is disposed so as to cover a second surface of the electronic component on an opposite side to a first surface of the electronic component, the first surface being opposed to one of the main surfaces of the printed board.

7. The semiconductor device according to claim 1, wherein
the printed board includes a plurality of the insulating layers, and
each of the plurality of insulating layers includes an inorganic filler particle.

8. The semiconductor device according to claim 1, wherein a groove connecting the radiation vias adjacent to each other in the plurality of radiation vias at the transmission viewpoint from one of the main surfaces of the printed board is formed in the printed board.

9. The semiconductor device according to claim 1, wherein a plurality of the thermal diffusers are disposed around the electronic component at the transmission viewpoint from one of the main surfaces of the printed board.

10. The semiconductor device according to claim 1, wherein
a plurality of the electronic components are disposed spaced apart from each other at the transmission viewpoint from one of the main surfaces of the printed board, and
a single of the thermal diffuser is disposed around each of the plurality of electronic components.

11. The semiconductor device according to claim 1, wherein bending rigidity of the thermal diffuser is higher than bending rigidity of the printed board.

12. The semiconductor device according to claim 1, wherein at least a part of the electronic component and the thermal diffuser is covered with a thermal diffusion material.
